(19) United States
(12) Patent Application Publication
(10) Pub. No.: US 2025/0007759 A1
(43) Pub. Date: Jan. 2, 2025

(54) METHODS AND APPARATUS FOR COMPLEX-ZERO EQUALIZERS

(71) Applicant: Intel Corporation, Santa Clara, CA (US)

(72) Inventors: Susnata Mondal, Hillsboro, OR (US); Mozhgan Mansuri, Portland, OR (US)

(21) Appl. No.: 18/344,730

(22) Filed: Jun. 29, 2023

(51) Int. Cl. H04L 25/03; H03F 1/32; H03F 3/45

(52) U.S. Cl. CPC H04L 25/03878; H03F 1/3211; H03F 3/45224

(57) ABSTRACT

Methods and apparatus are disclosed for complex-zero equalizers. An example circuit comprises driver circuitry including a first input, and equalizer circuitry including a second input, a first output coupled to the first input, a transistor including a gate terminal, a drain terminal, and a source terminal, the gate terminal coupled to the second input and the drain terminal coupled to the first output, an inductor including a first inductor terminal and a second inductor terminal, the first inductor terminal coupled to the source terminal of the transistor, a resistor coupled to the second inductor terminal, and a capacitor including a first terminal and a second terminal coupled to the source terminal and to the first inductor terminal and the second terminal coupled to ground.

### FIELD OF THE DISCLOSURE

This disclosure relates generally to equalizers and, more particularly, to methods and apparatus for a complex-zero equalizer.

### BACKGROUND

A wideband system is a system or device that operates over a broad range of frequencies. Wideband systems are applied in various fields, including telecommunications, radio and television broadcasting, radar systems, satellite communication, medical imaging, high-speed data acquisition, etc. Wideband systems are commonly used for high-speed data transmission because they enable the transmission of a large amount of information quickly. Therefore, wideband systems play a critical role in modern communication, where there is an increasing demand for faster data transmission.

### BRIEF DESCRIPTION OF THE DRAWINGS

FIG. 1 is a schematic illustration of an example communication channel showing the frequency response of a channel.

FIG. 2 is a schematic illustration of an example transistor to implement examples disclosed herein.

FIG. 3 is a schematic illustration of a simplified vertical cavity surface emitting laser (VCSEL) model including a complex pole.

FIG. 4 is a block diagram of an example VCSEL driver system including an example first complex-zero continuous time linear equalizer (CTLE) to cancel an effect of the complex pole of the VCSEL model of FIG. 3.

FIG. 5 is a schematic illustration of the example first complex-zero CTLE circuitry of FIG. 4 that cancels the effect of the complex pole of the VCSEL model of FIG. 3.

FIG. 6 is an example frequency response graph of example optical frequency responses across VCSEL bias, an example conventional CTLE response, and an example complex-zero CTLE response.

FIG. 7 is a schematic illustration of example second complex-zero CTLE circuitry.

FIG. 8 is a graphical representation of an example first VCSEL group delay response graph across three bias currents of the VCSEL of FIG. 3, an example first CTLE response graph of the second complex-zero CTLE circuitry of FIG. 7, an example second CTLE response graph of the second complex-zero CTLE circuitry of FIG. 7, and an example third response graph of the second complex-zero CTLE circuitry of FIG. 7.

FIG. 9 is an example system diagram of an example VCSEL driver including the example second complex-zero CTLE circuitry of FIG. 7.

FIG. 10 is an example first group delay response graph comparing a group delay response of an example VCSEL, an example conventional CTLE, and the example second complex-zero CTLE circuitry of FIG. 7 and an example second group delay response graph comparing group delay response and gain response of a VCSEL implementing the example conventional CTLE and the example second complex-zero CTLE circuitry of FIG. 7.

FIG. 11 is a schematic illustration of example third complex-zero CTLE circuitry.

FIGS. 12A, 12B, and 12C are schematic illustrations of different applications of the example first complex-zero CTLE circuitry of FIG. 5.

FIG. 13 is a flowchart representative of example operations of the example complex-zero CTLE circuitry of FIGS. 4, 5, 7, and 11 to cancel an effect of a complex pole in a frequency response of wideband system.

In general, the same reference numbers will be used throughout the drawing(s) and accompanying written description to refer to the same or like parts. The figures are not necessarily to scale. Instead, the thickness of the layers or regions may be enlarged in the drawings. Although the figures show layers and regions with clean lines and boundaries, some or all of these lines and/or boundaries may be idealized. In reality, the boundaries and/or lines may be unobservable, blended, and/or irregular.

As used herein, unless otherwise stated, the terms “on top of” or “above” describe the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

Notwithstanding the foregoing, in the case of referencing a semiconductor device (e.g., a transistor), a semiconductor die containing a semiconductor device, and/or an integrated circuit (IC) package containing a semiconductor die during fabrication or manufacturing, “above” is not with reference to Earth, but instead is with reference to an underlying substrate on which relevant components are fabricated, assembled, mounted, supported, or otherwise provided. Thus, as used herein and unless otherwise stated or implied from the context, a first component within a semiconductor die (e.g., a transistor or other semiconductor device) is “above” a second component within the semiconductor die when the first component is farther away from a substrate (e.g., a semiconductor wafer) during fabrication/manufacturing than the second component on which the two components are fabricated or otherwise provided. Similarly, unless otherwise stated or implied from the context, a first component within an IC package (e.g., a semiconductor die) is “above” a second component within the IC package during fabrication when the first component is farther away from a printed circuit board (PCB) to which the IC package is to be mounted or attached. It is to be understood that semiconductor devices are often used in orientation different than their orientation during fabrication. Thus, when referring to a semiconductor device (e.g., a transistor), a semiconductor die containing a semiconductor device, and/or an integrated circuit (IC) package containing a semiconductor die during use, the definition of “above” in the preceding paragraph (i.e., the term “above” describes the relationship of two parts relative to Earth) will likely govern based on the usage context.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly within the context of the discussion (e.g., within a claim) in which the elements might, for example, otherwise share a same name.

As used herein, “approximately” and “about” modify their subjects/values to recognize the potential presence of variations that occur in real world applications. For example, “approximately” and “about” may modify dimensions that may not be exact due to manufacturing tolerances and/or other real world imperfections as will be understood by persons of ordinary skill in the art. For example, “approximately” and “about” may indicate such dimensions may be within a tolerance range of +/−10% unless otherwise specified in the below description.

As used herein, the phrase “in communication,” including variations thereof, encompasses direct communication and/or indirect communication through one or more intermediary components, and does not require direct physical (e.g., wired) communication and/or constant communication, but rather additionally includes selective communication at periodic intervals, scheduled intervals, aperiodic intervals, and/or one-time events.

As used herein integrated circuit/circuitry is defined as one or more semiconductor packages containing one or more circuit elements such as transistors, capacitors, inductors, resistors, current paths, diodes, etc. For example, an integrated circuit may be implemented as one or more of a semiconductor-based laser diode, an ASIC, an FPGA, a chip, a microchip, programmable circuitry, a semiconductor substrate coupling multiple circuit elements, a system on chip (SoC), etc.

### DETAILED DESCRIPTION

Data can be transmitted in parallel or in serial. In some examples, when data is transmitted at high frequencies, a problem occurs. For example, in parallel transmission, capacitance exists between two parallel data lines (e.g., two wires running parallel with respect to each other). Capacitance includes reactance (e.g., the resistance of capacitance), which is a function of frequency. For example, reactance between parallel lines that are capacitively coupled decreases when frequency increases. In some examples, the capacitance between two parallel data lines functions as a short between the lines at high frequencies when the reactance decreases. Therefore, at high frequencies, data on one parallel line might interfere with data on the other parallel line and the data will be corrupted by the time the receiver obtains it. In some examples, one of the parallel lines could be a ground line or a ground plane. In such an example, capacitive coupling exists between a data line and ground.

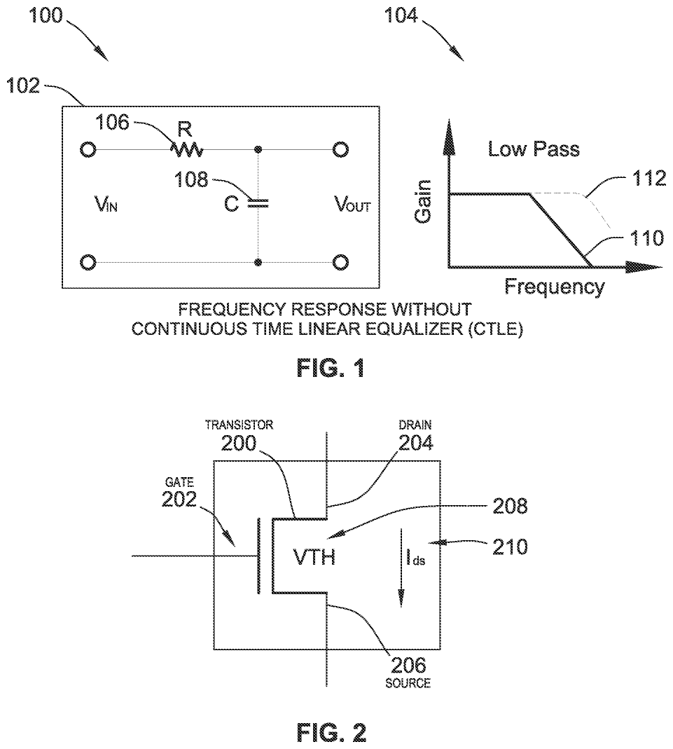

In some examples, this corruption is sometimes referred to as channel attenuation. Channel attenuation is a loss of signal strength or a distortion of a signal when transmitting data. Channel attenuation can occur due to a number of different factors other than corruption, such as electromagnetic interference (EMI), distance between transmitter and receiver, and even channel characteristics. For example, at high frequencies, an amplitude or gain of a signal decreases due to resistive and reactive characteristics of the channel. In some examples, the channel acts as a filter (e.g., a low pass filter or a high pass filter) due to its resistance and reactance, as shown in FIG. 1 and described in further detail below. To negate the effects of channel attenuation, transmitters and receivers implement equalizers (e.g., continuous time linear equalizer (CTLE)).

FIG. 1 illustrates a schematic illustration of an example communication channel 100 showing the frequency response of a channel. The example communication channel 100 of FIG. 1 includes an example resistance-capacitance (RC) filter 102 and an example frequency response graph 104. The example RC filter 102 includes an example resistor (R) 106 and an example capacitor (C) 108. The example frequency response graph 104 includes a first gain line 110 and a second gain line 112.

In FIG. 1, the example resistor (R) 106 depicts a resistance of the communication channel 100. For example, a wire, trace pad, etc., may have characteristics that act as a resistance to electrical current.

In FIG. 1, the example capacitor (C) 108 depicts a capacitance between the communication channel 100 with respect to ground. For example, inherent capacitance can exist between closely spaced conductors, such as traces on a printed circuitry board (PCB) or wires in a cable.

In FIG. 1, the example first gain line 110 illustrates a gain of the input signal (V_{IN}) as it passes through the example RC filter 102. Gain of a signal refers to an amplification or multiplication factor by which the signal is increased or decreased in magnitude. The gain represents a ratio of the output signal (V_{OUT}) amplitude to the input signal (V_{IN}) amplitude.

In FIG. 1, the example second gain line 112 illustrates a gain of the input signal (V_{IN}) if an equalizer were applied to the example RC filter 102. For example, the second gain line 112 illustrates a desired gain of an input signal (V_{IN}) that can be achieved through the use and/or application of a CTLE. In some examples, an equalizer achieves the desired gain of the input signal and, thus, equalizes the transmitter. In some examples, an equalizer can be used to equalize an input signal at a receiver, once the receiver obtains a signal from a transmitter.

As described above, capacitors (e.g., C 108) have reactance (X_{C}), which is a function of frequency. Capacitive reactance (X_{C}) of the example capacitor (C) 108 affects an output (V_{OUT}) of the channel. For example, the inherent capacitance of the communication channel 100 (shown by C 108) can cause an output signal to decrease depending on the frequency at which the signal is being transmitted. Capacitive reactance is measured by Equation 1 below, were X_{C} is capacitive reactance, f is frequency (Hz), and C is capacitance (farads).

$$\\ \begin{matrix}{X}_{C} = \frac{1}{2 π fC} & ( Equation 1 )\end{matrix}$$

In Equation 1, C is constant. Therefore, in an example operation of the example RC filter 102, the capacitive reactance (X_{C}) will change based on the frequency. In an example first operation, when an input signal (V_{IN}) having a low frequency is applied to the RC filter 102, X_{C} will be high and the communication channel 100 will pass the input signal (V_{IN}) to the output. In an example second operation, when the input signal (V_{IN}) is applied to the RC filter 102 and includes a high frequency, X_{C} will be low and the capacitor (C) 108 will act as a short to ground. As such, a majority of the input signal (V_{IN}) will be shorted to ground and the communication channel 100 will not pass the high frequency input signal (V_{IN}) to the output.

The example frequency response graph 104 illustrates the example first and second operations of the RC filter 102 described above. At low frequencies, the capacitor 108 effectively appears as an open circuit. As such, at lower frequencies, the first gain line 110 is high. Therefore, the example RC filter 102 is passing a majority (if not all) of the input signal (V_{IN}) to the output (V_{OUT}). In the example second operation, the first gain line 110 decreases at higher frequencies. Therefore, the higher the frequency, the less input signal (V_{IN}) the RC filter 102 passes to the output (V_{OUT}).

It is therefore desirable to implement equalizers, such as CTLEs, before a gain stage in a transmitter or a receiver in order to ensure that at higher frequencies, a majority of the input signal (V_{IN}) will be passed to the output (V_{OUT}). For example, an equalizer is located between an input stage and an output stage of a transmitter or a receiver in order to equalize an input signal and provide the equalized input signal to an output stage.

In some examples, an equalizer compensates for the attenuation of a channel at higher frequencies. For example, referring to the frequency response graph 104 of FIG. 1, channel attenuation occurs between a first frequency at which the first gain line 110 starts to decrease (e.g., the cutoff frequency) and a second frequency at which the first gain line 110 is zero. An equalizer increases the gain of an input signal applied at any frequency between the cutoff frequency and the second frequency. For example, if the cutoff frequency is 1 GHz, the second frequency is 10 GHz, and the input signal is 5 GHz, the equalizer increases a gain of the input signal to compensate for the attenuation that the 5 GHz signal will experience through the channel. Therefore, instead of the input signal having a gain as depicted by the first gain line 110, the input signal will have a gain as depicted by the second gain line 112 due to boosting of certain input frequencies.

One type of equalizer is a continuous time linear equalizer (CTLE). CTLEs are used in communication systems to compensate for channel distortions and improve the overall signal quality. While CTLEs offer benefits, CTLEs also pose issues that should be considered. One of the issues CTLEs pose is a limited equalization range. For example, CTLEs are effective in compensating for frequency-dependent losses and distortions within a certain frequency range (e.g., bandwidth). However, beyond this bandwidth, CTLE equalization performance may degrade and limit their usefulness in compensating for channel impairments or frequency deviations. For example, in wideband systems (e.g., optical transmitters, shunt-peaking systems, packaging interfaces, etc.), equalization is limited by the presence of in-band complex pole pairs and higher-order amplitude roll-off.

A complex pole pair refers to a pole in a transfer function, which represents the relationship between an input signal and an output signal in a wideband system, that has both a real part and an imaginary part. The real part of a complex pole affects the decay or growth of the response (e.g., transfer function) over time, while the imaginary part determines the oscillatory or resonant behavior of the response (e.g., transfer function) at a particular frequency. For example, if the poles of the transfer function have negative real parts, the wideband system exhibits a decay behavior, which means that the amplitude of the output signal decreases over time or as the frequency increases. And if the poles of the transfer function have positive real parts, the wideband system exhibits a growth behavior, which means that the amplitude of the output signal increases over time as frequency increases. In some examples, a complex pole pair with a positive imaginary part can result in oscillatory or resonant behavior, while a complex pole pair with a negative imaginary part can result in a damped response.

An in-band complex pole pair is a pair of complex poles that exist within a signal bandwidth (e.g., a frequency range of interest). When complex poles exist in the bandwidth, they can affect the frequency response of the wideband system by introducing peaks or notches at specific frequencies. In some examples, the effect of the complex poles is advantageous. In some examples, the effect of the complex poles is disadvantageous due to the instability, excessive peaking, or unwanted resonances that it causes within the desired bandwidth.

The higher-order amplitude roll-off of a wideband system refers to a rate at which the wideband system attenuates or reduces the amplitude of higher-frequency components in the frequency response. In wideband systems, the amplitude roll-off characterizes how the gain or amplification changes as the frequency increases. A higher-order roll-off means that the system provides increasing attenuation for higher frequencies, resulting in a steeper decrease in amplitude response. The amplitude roll-off is typically specified in terms of decibels per octave (dB/octave) or decibels per decade (dB/decade). These units represent the rate of change in attenuation as the frequency doubles (octave) or increases tenfold (decade). For example, a wideband system with a 6 db/octave roll-off means that the amplitude decreases by 6 dB for every doubling of frequency, while a wideband system with a 20 dB/decade roll-off means that the amplitude decreases by 20 dB for every tenfold increase in frequency. Higher-order amplitude roll-offs are often desired in wideband system designs to achieve sharper equalization and better compensation for higher-frequency distortions or channel impairments. However, wideband systems (e.g., optical transmitters, shunt-peaking systems, packaging interfaces, etc.) can be limited by higher-order amplitude roll-off. For example, if the roll-off is too aggressive, it may attenuate or suppress desired signal components within the wideband frequency range, leading to a loss of information or degraded system performance.

There is a greater demand for higher operating bandwidth because there is a desire for higher communication link data rates. Examples disclosed herein provide a complex-zero CTLE architecture that cancels an effect of a complex pole pair using a complex-zero pair and can perform second-order gain equalization. For example, while a conventional CTLE uses a parallel R-C network at a source of a common source amplifier to introduce a real-zero in the amplitude response, examples disclosed herein use an inductor (L) in series with the resistor of the R-C network. In examples disclosed herein, the inductor (L) in series with the resistor of the R-C network introduces a complex-zero to the frequency response. Poles are the points in the complex plane (e.g., real axis and imaginary axis) where the transfer function becomes infinite or undefined, while zeros are the points where the transfer function becomes zero. The presence of complex-zero pairs in the transfer function (e.g., the response of the CTLE) allows for targeted shaping of the frequency response, by attenuating or enhancing specific frequency components.

Examples disclosed herein implement the complex-zero CTLE architecture in any wideband system, such as vertical-cavity surface emitting laser (VCSEL) based optical links, shunt-peaking systems, and packaging interfaces. In an example VCSEL, examples disclosed herein cancel an effect the complex pole pair has on an optical part of the frequency response by generating a positive amplitude roll-off. For example, an optical part of the VCSEL frequency response includes negative second order (e.g., 40 dB/decade) roll-off due to the presence of a complex pole pair. The example the inductor (L) of the complex-zero CTLE architecture achieves a positive (e.g., +40 db/decade) amplitude roll-off to equalize the negative (e.g., −40 dB/decade) roll-off of the VCSEL optical response. A VCSEL and an optical response of the VCSEL is described in further detail below in connection with FIG. 3.

In some examples, a conventional CTLE includes a real-zero in the transfer function that cannot equalize for the gain and group delay peaking introduced by a complex pole pair, such as the gain and group delay peaking in VCSEL's electro-optical frequency response. As used herein, group delay is an amount of time it takes for a signal to pass through a circuit. Specifically, group delay is measured and plotted with respect to frequency, as signals at some frequencies may take longer to pass through a circuit than others due to a reactive nature of certain components in the system. As used herein, group delay peaking is a phenomenon where certain frequencies experience an increase in group delay in the communication system (e.g., wideband system) that cannot be equalized using conventional real-zero equalizer. Moreover, a conventional CTLE can perform only first order gain equalization due to the single real-zero in the response.

In some examples, conventional complex-zero equalization methods are used to equalize gain and group delay peaking introduced by a complex pole pair. For example, conventional complex-zero equalization methods include a low-pass path transfer function combined with and a high-pass path transfer function to equalize gain and group delay peaking. However, this complex-zero equalizer is complex and involves multiple stages that degrade energy efficiency and make it difficult, if not impossible, to implement for higher data rates. Therefore, examples disclosed herein improve and simplify conventional complex-zero equalization techniques.

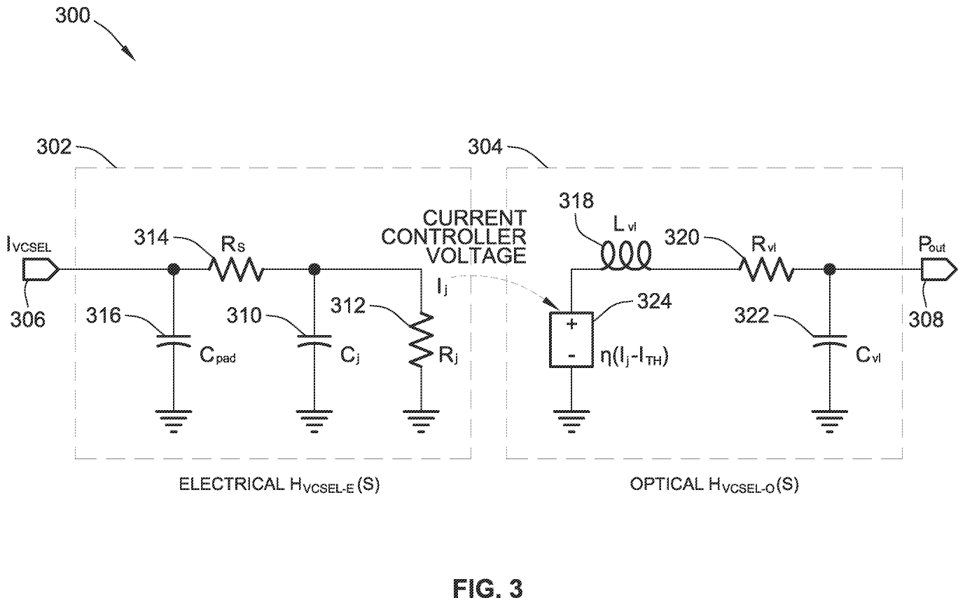

FIG. 2 is a schematic illustration of an example transistor 200 to implement examples disclosed herein. The example transistor 200 of FIG. 2 represents structure and characteristics of n-channel metal-oxide semiconductor (NMOS) transistors that may be used to implement an equalizer, input stages, gain stages, output stages, and/or any other circuitry of a wideband system, such as a vertical-cavity surface emitting laser (VCSEL), a shunt-peaking system, etc. The example transistor 200 includes a gate terminal 202, a drain terminal 204, and a source terminal 206. In some examples, the gate terminal 202 is a control terminal. In some examples, the drain terminal 204 and the source terminal 206 are current terminals. The example transistor 200 operates at a particular threshold voltage (V_{TH}) 208. The value of the V_{TH} 208 depends on a supply voltage level (e.g., VCC) at which the transistor 200 is intended to operate. When a voltage level applied at the example gate terminal 202 satisfies (e.g., is greater than) the V_{TH} 208 of the transistor 200 (e.g., the applied voltage level is at logic level high “1”), the transistor 200 is referred to as being in an “on” state and creates a closed circuit between the drain terminal 204 and the source terminal 206 causing drain-to-source electrical current (I_{ds}) 210 to flow between the drain terminal 204 and the source terminal 206 of the transistor 200 (e.g., I_{ds}=I_{ON}). When the voltage level applied to the example gate terminal 202 does not satisfy (e.g., is less than) the V_{TH} 208 of the transistor 200 (e.g., the applied voltage level is at logic level low “0”), the transistor 200 is referred to as being in an “off” state and creates an open circuit between the drain terminal 204 and the source terminal 206 causing drain-to-source electrical current (I_{ds}) 210 to cease (e.g., I_{ds}=I_{OFF}).

Although not shown in FIG. 2, another type of transistor is a p-channel metal-oxide semiconductor (PMOS) transistor. In examples disclosed herein, PMOS transistors are represented with circles at their gate terminals. The “on” and “off” states of a PMOS transistor are activated based on opposite inputs at its gate terminal relative to the NMOS transistor. For example, when a voltage level applied at the gate terminal of a PMOS transistor satisfies (e.g., is greater than) the V_{TH} of the PMOS transistor (e.g., the applied voltage level is at logic level high “1”), the PMOS transistor is referred to as being in an “off” state, and when a voltage level applied at the gate terminal of the PMOS transistor does not satisfy (e.g., is less than) the V_{TH} of the PMOS transistor (e.g., the applied voltage level is at logic level low “0”), the PMOS transistor is referred to as being in an “on” state.

FIG. 3 is a schematic illustration of a simplified vertical cavity surface emitting laser (VCSEL) model 300. A VCSEL is a semiconductor laser, where the semiconductor emits light in a direction perpendicular to the VCSEL surface. A VCSEL can be directly modulated (e.g., the current of a VCSEL can be varied with a modulation signal that contains information to be transmitted) through electrical signals, making the VCSEL useful for high-speed data communication, such as optical fiber communication. Optical fibers can be used to transmit light and, thus, information, over long distances. An example VCSEL includes an active region (e.g., a resonator) located between two semiconductors (e.g., two semiconductor Bragg mirrors). The VCSEL converts electrical signals to optical signals. For example, an electrical portion of the VCSEL provides and modulates the active region of the VCSEL with current in order to generate light. The active region consists of multiple quantum wells, which are thin layers of semiconductor material that confine electrons and holes. Therefore, when a current passes through the active region, electrons and holes recombine and, thus, release energy in the form of photons. The electrical portion of the VCSEL controls the current injected into the active region in order to modulate the VCSEL in a manner that achieves a desired output power. An optical portion of the VCSEL emits the photons, allowing for light to be emitted vertically (e.g., perpendicular) from the VCSEL surface.

In FIG. 3, the example simplified VCSEL model 300 includes an example electrical model 302 and an example optical model 304. The example electrical model 302 models electrical parameters and characteristics of the electrical portion of a VCSEL. For example, the electrical model 302 models how an example modulated input current (I_{VCSEL}) 306 is effected by the VCSEL. The example optical model 304 models optical parameters and characteristics of the optical portion of a VCSEL. For example, the optical model 304 models how the example modulated input current (I_{VCSEL}) 306 effects a gain of an example optical output (Pₒᵤₜ) 308.

In FIG. 3, the example electrical model 302 includes an example junction capacitor (Cⱼ) 310, an example junction resistor (Rⱼ) 312, an example series resistor (Rₛ) 314, and an example pad capacitor (C_{pad}) 316. The example junction capacitor (Cⱼ) 310 is coupled in parallel with the example junction resistor (Rⱼ) 312. The example junction capacitor (Cⱼ) 310 is coupled to the example series resistor (Rₛ) 314. The example series resistor (Rₛ) 314 is coupled to the modulated input current (I_{VCSEL}) 306 and to the example pad capacitor (C_{pad}) 316.

In FIG. 3, the example junction capacitor (Cⱼ) 310 and the example junction resistor (Rⱼ) 312 represent junction resistance and capacitance. In some examples, the junction resistance and capacitance is the resistance and capacitance of the active region of the VCSEL. When a voltage is applied across the junction, it creates an electric field that drives the flow of electrons and holes of the quantum wells to the active region. Therefore, the junction resistance (Rⱼ 312) and junction capacitance (Cⱼ 310) of the VCSEL affect the modulated input current (I_{VCSEL}) 306. For example, the modulated input current (I_{VCSEL}) 306 gets diverted to junction capacitor (Cⱼ) 310 which creates a low impedance path at high frequencies. The actual amount of current available for electrical to optical conversion is represented by the current (Iⱼ) flowing into the example junction resistor (Rⱼ) 312.

In FIG. 3, the example pad capacitor (C_{pad}) 316 represents a capacitance of the pad (e.g., electrical contact) on the active region (e.g., junction, P-N junction, etc.). For example, electrical contacts are placed on p-type and an n-type layers to provide a path for the flow of modulated input current (I_{VCSEL} 306) into the VCSEL. In some examples, the pad capacitor (C_{pad}) 316 also represents parasitic capacitance (e.g., unwanted capacitance) and, thus, the modulated input current (I_{VCSEL}) 306 gets diverted to both the pad capacitor (C_{pad}) 316 and junction capacitor (Cⱼ) 310, which creates the low impedance path at high frequencies.

In FIG. 3, the example optical model 304 includes an example series inductor (Lᵥₗ) 318, an example series resistor (Rᵥₗ) 320, and an example series capacitor (Cᵥₗ) 322. The example series inductor (Lᵥₗ) 318, the example series resistor (Rᵥₗ) 320, and the example series capacitor (Cᵥₗ) 322 are driven by an example voltage source 324 of value η (Iⱼ−I_{TH}), where n represents a slope efficiency (e.g., linearity of the VCSEL output) and I_{TH} is a threshold current of the VCSEL. The example series inductor (Lᵥₗ) 318 is coupled in series to the example series resistor (Rᵥₗ) 320 and to the example voltage source 324. The example series resistor (Rᵥₗ) 320 is coupled to the example series capacitor (Cᵥₗ) 322. In FIG. 3, a voltage of example series capacitor (Cᵥₗ) 322 is used as the output (Pₒᵤₜ) 308.

In some examples, the gain of Pₒᵤₜ 308 can be measured by Equation 2 below, where H_{VCSEL-E}(s) is the frequency response of the electrical model 302, H_{VCSEL-O}(s) is the frequency response of the optical model 304, η is the slope efficiency, Lᵥₗ is an inductance in Henries (H) of the series inductor (Lᵥₗ) 318, and Cᵥₗ is a capacitance in farads (F) of series capacitor (Cᵥₗ) 322.

$$\\ \begin{matrix}gain = \frac{{H}_{VCSEL - E} ( S ) \times η [ 1 / {L}_{vl} {C}_{vl} ]}{{H}_{VCSEL - O} ( S )} & ( Equation 2 )\end{matrix}$$

In some examples, the frequency response H_{VCSEL-O}(s) of the optical model 304 can be measured by Equation 3 below, where s is a complex variable denoting an imaginary part (j) times omega (ω) (e.g., ω=2πf), and Rᵥₗ is the resistance in Ohms (Ω) of the series resistor (Rᵥₗ) 320.

$$\\ \begin{matrix}{H}_{VCSEL - O} ( S ) = {s}^{{}_{} 2} + ( {R}_{vl} / {L}_{vl} ) s + 1 / {L}_{lv} {C}_{vl} & ( Equation 3 )\end{matrix}$$

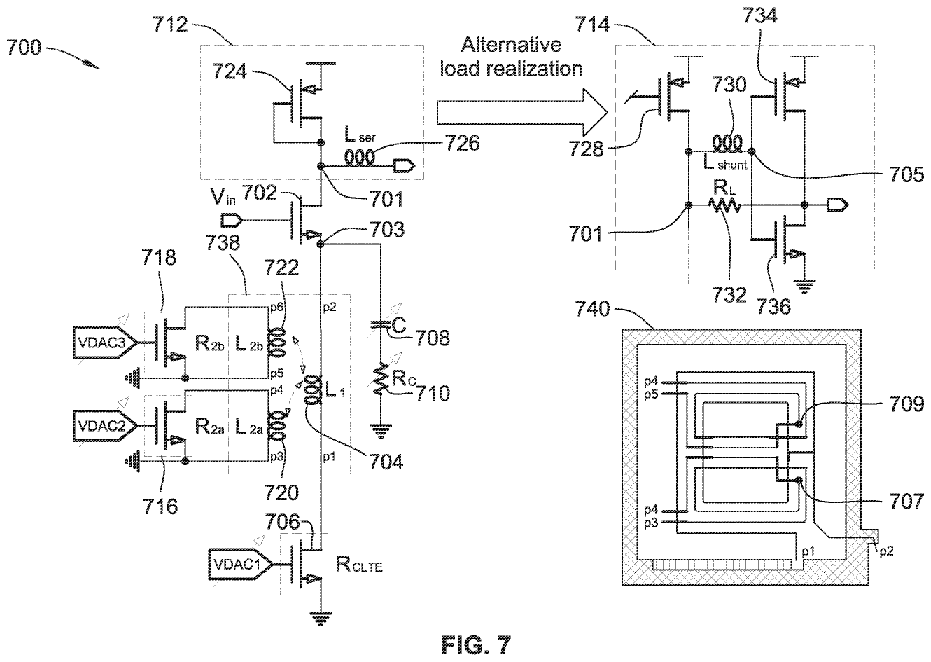

In some examples, the series inductor (Lᵥₗ) 318, series resistor (Rᵥₗ) 320, and series capacitor (Cᵥₗ) 322 introduce a complex pole pair in the optical frequency response H_{VCSEL-O}(s) of the VCSEL. As a result of the complex pole pair, the optical frequency response H_{VCSEL-O}(s) has a second order (40 dB/decade) roll-off, in-band gain peaking (e.g., less than 3 dB) and group delay distortion (e.g., less than 10 picoseconds). Examples disclosed herein implement a complex-zero CTLE to equalize the second order roll-off, the in-band gain peaking, and the group delay distortion. For example, the complex-zero CTLE architecture reduces the gain variation and group delay distortion of the frequency response of the VCSEL while additionally correcting some of the second order roll-off in order to extend the overall bandwidth of the VCSEL. An example of the optical frequency response H_{VCSEL-O}(s) is described in further detail below in connection with FIG. 6. The complex-zero CTLE architecture is not limited to the VCSEL. For example, the complex-zero CTLE architecture can extend to any system having similar issues (e.g., group delay distortion, gain variation, and second order roll offs).

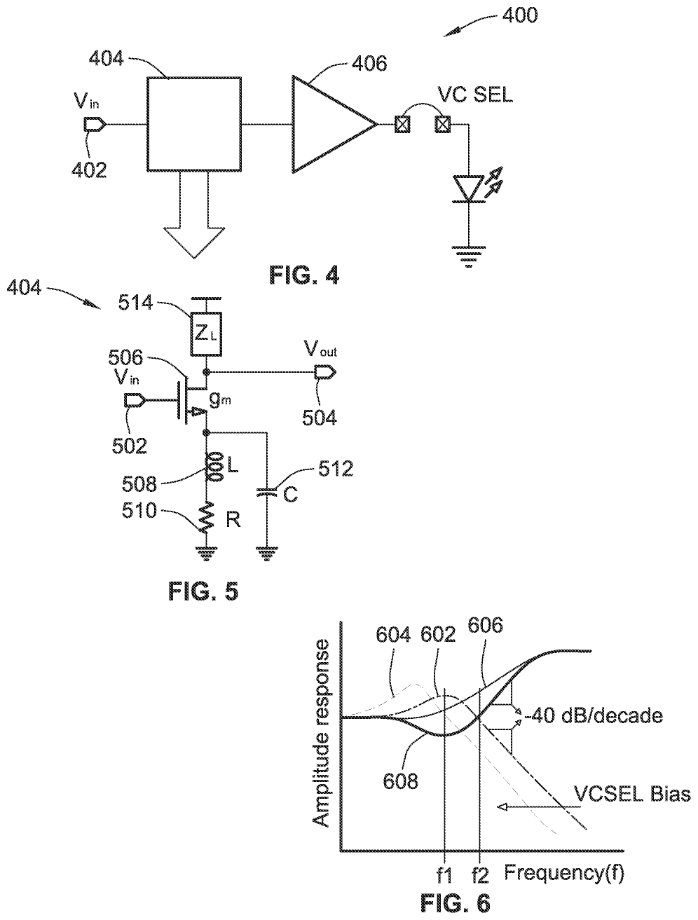

FIG. 4 is a block diagram of an example VCSEL driver system 400 including example first complex-zero CTLE circuitry 404 to cancel an effect of the complex pole of the VCSEL. In some examples, the first complex-zero CTLE circuitry 404 is equalizer circuitry, an equalizer circuit, etc. In some examples, the VCSEL driver system 400 modulates the input to the VCSEL based on an input signal (Vᵢₙ) 402. For example, the VCSEL input current is to be modulated by driver circuitry in order to achieve a target optical modulation amplitude (OMA). OMA is a specific required modulation value that ensures a receiver receives a signal that is the same as the signal that was sent by the VCSEL. For example, laser modulation is defined between a high (P1) and low (P0) output level, which represent the ones and zeros, at a specified rate that is determined by the data rate of the link. The actual output power is the biased voltage applied to the laser output while the receiver sensitivity is the minimum amount of light received where the modulation can accurately be determined. Problems occur when a receiver is not able to determine whether the light level at a given time is at the high or low level. Therefore, OMA is a value that, when met, establishes that there is enough of a change from the high level to the low level that the receiver will be able to discern between the two, regardless of whether the link is short or approaches the maximum allowable link length.

In FIG. 4, the example VCSEL driver system 400 includes example first complex-zero CTLE circuitry 404, example driver circuitry 406, and an example laser diode 408. In some examples, the example laser diode 408 is a VCSEL and is represented by the example electrical model 302 of FIG. 3 and the example optical model 304 of FIG. 3. In some examples, the driver circuitry 406 is a driver circuit.

In FIG. 4, an input of the example first complex-zero CTLE circuitry 404 is coupled to the input signal (Vᵢₙ) 402 and an output of the first complex-zero CTLE circuitry 404 is coupled to an input of the example driver circuitry 406. An output of the example driver circuitry 406 is coupled to an input of the example laser diode 408.

In FIG. 4, the example driver circuitry 406 is to perform signal amplification of the input signal (Vᵢₙ) 402 while also equalizing VCSEL's frequency response, consisting of an electrical part and an optical part, in order to improve link data rates. However, the example driver circuitry 406 does not equalize the VCSEL's frequency response. Therefore, the example VCSEL driver system 400 includes the example first complex-zero CTLE circuitry 404 to equalize the VCSEL's frequency response. The example first complex-zero CTLE circuitry 404 is described in further detail below in connection with FIG. 5.

FIG. 5 is a schematic illustration of the example first complex-zero CTLE circuitry 404 that cancels the effect of the complex pole of the VCSEL of FIG. 3. The example first complex-zero CTLE circuitry 404 includes an input (Vᵢₙ) 502, an output (Vₒᵤₜ) 504, an example first transistor 506, an example first inductor 508, an example first resistor 510, an example first capacitor 512, and an example load impedance 514.

In FIG. 5, the example first transistor 506 is an NMOS transistor and includes a gate terminal (e.g., a control terminal, a base terminal, etc.), a drain terminal (e.g., a current terminal), and a source terminal (e.g., a current terminal). Additionally and/or alternatively, the example first transistor 506 may be any type of transistor, such as a bipolar junction transistor (BJT), field-effect transistors (FETs), insulated-gate bipolar transistors (IGBTs), etc. The gate terminal of the example first transistor 506 is coupled to the example input (Vᵢₙ) 502. The drain terminal of the example first transistor 506 is coupled to example load impedance 514. The source terminal of the example first transistor 506 is coupled to a first terminal of the example first inductor 508 and a first terminal of the example first capacitor 512. The example output (Vₒᵤₜ) 504 is tied to the drain terminal of the example first transistor 506. The example first inductor 508 is coupled between the source terminal of the example first transistor 506 and the example first resistor 510. For example, a second terminal of the first inductor 508 is coupled to the first resistor 510 while the first terminal of the first inductor 508 is coupled to the source terminal of the first transistor 506. The example first resistor 510 is coupled between the example first inductor 508 and ground. The first terminal of the example first capacitor 512 is coupled between the source terminal of the first transistor 506 and the first terminal of the first inductor 508, and a second terminal of the first capacitor 512 is coupled to ground.

In FIG. 5, the example first transistor 506 is a common source amplifier, wherein the load impedance 514 acts as a biasing network in order to ensure a desired operation of the first transistor 506. For example, a common source amplifier is used to amplify input signals (e.g., Vᵢₙ 502) based on the biasing conditions set by the biasing network. In some examples, the input signal (e.g., Vᵢₙ 502) is applied to the gate terminal of the first transistor 506 to modulate a width of the channel between the drain terminal and the first terminal of the first transistor 506, thereby controlling the current through the first transistor 506. The changing drain current (I_{D}) causes an amplified output (Vₒᵤₜ) 504 at the drain terminal. In some examples, a gain of the common source amplifier (e.g., the first transistor 506) is determined by a ratio of the output voltage (Vₒᵤₜ) to the input voltage (Vᵢₙ). The gain of the first transistor 506 is affected by an impedance (Z) of the first inductor 508, the first resistor 510, and the first capacitor 512, and a transconductance (gₘ) of the first transistor 506. In some examples, the transconductance (gₘ) is the ratio of the change in drain current (I_{D}) to the change in input voltage (Vᵢₙ) at the gate terminal. In some examples, the gain of the first transistor 506 is affected by the load impedance 514. For example, a portion of the amplified output voltage is dropped across the load impedance 514, reducing the voltage available at the output (Vₒᵤₜ) 504.

In FIG. 5, the example first inductor 508, the example first resistor 510, and the example first capacitor 512 are implemented by the example first complex-zero CTLE circuitry 404 to introduce a complex-zero in a CTLE frequency response in order to equalize and/or cancel the effects (e.g., the second order roll-off, the in-band gain peaking, and the group delay distortion) of the VCSEL frequency response and/or any similar affects present in a frequency response of any wideband system.

In a conventional CTLE, the R-C network coupled to the source of the common source amplifier was designed to provide a real-zero in the amplitude response of the conventional CTLE. For example, in a CTLE with an R-C network, the resistor provides source degeneration (e.g., negative feedback) to decrease the gain of the common source amplifier. In order to change (e.g., increase and decrease) the gain of the common source amplifier at certain frequencies, the capacitor is coupled in parallel to the resistor. The capacitor changes the impedance of the common source amplifier and, thus, changes the gain. For example, as described above, capacitive reactance (X_{c}) is a function of frequency and indicates whether the capacitor is an open circuit or a closed circuit (e.g., a short circuit). For example, when the frequency is zero, capacitive reactance is infinity, meaning the capacitor is open and the resistance/impedance in the common source amplifier comes from the full resistance of the resistor. In such an example, the gain of the common source amplifier decreases. In some examples, when the frequency increases, capacitive reactance decreases, meaning the capacitor acts (or begins to act) like a short circuit and the resistance/impedance in the common source amplifier decreases. In such an example, the gain of the common source amplifier increases. Therefore, the capacitor coupled in parallel to the resistor introduces a zero (e.g., a real-zero) in the frequency response of the common source amplifier. However, as described above, the real-zero cannot equalize for the gain variation and group delay peaking introduced by a complex pole pair, such as the gain variation and group delay peaking in VCSEL's electro-optical frequency response.

In FIG. 5, the example first inductor 508 coupled in series with the example first resistor 510 generates the complex-zero to cancel out the complex pole of the VCSEL frequency response, wherein the complex pole causes the second order roll-off, the in-band gain peaking, and the group delay distortion in the VCSEL frequency response. For example, the first inductor 508 and the first resistor 510 form an LR circuit. In some examples, frequency affects the LR circuit. For example, the first inductor 508 includes inductive reactance (X_{L}) which is a function of frequency (e.g., X_{L}=2πfL), where X_{L} decreases when frequency decreases and X_{L} increases when frequency increases. The inductive reactance (X_{L}) of the first inductor 508 and the resistance of the first resistor 510 combine to form impedance (Z). Impedance (Z) in an LR circuit is the total opposition to the flow of current and is a complex quantity that includes both resistance and reactance. When inductive reactance increases, so does impedance (Z). This means that at higher frequencies, the first inductor 508 offers greater opposition to the flow of current.

In some examples, the first inductor 508, the first resistor 510, and the first capacitor 512 act together to decrease the gain of the first complex-zero CTLE circuitry 404 at a particular frequency and to increase the gain of the first complex-zero CTLE circuitry 404 at one or more particular frequencies. For example, the first inductor 508, the first resistor 510, and the first capacitor 512 are given values (e.g., resistance value, inductance value, and capacitance value) that cause the first complex-zero CTLE circuitry 404 to output a particular gain at a particular frequency in order to cancel out the complex pole of the VCSEL. The gain of the example first complex-zero CTLE circuitry 404 can be measured by Equation 4 below, where gₘ is the transconductance of the first transistor 506, Z_{L} is the impedance of the first inductor 508, s is a complex variable denoting an imaginary part (j) times omega (ω) (e.g., ω=2πf), R is the resistance in Ohms (Ω) of the first resistor 510, L is the inductance in Henries of the first inductor 508, and C is the capacitance in farads of the first capacitor 512.

$$\\ \begin{matrix}CTLE gain = \frac{{g}_{m} {Z}_{L} [ {s}^{{}_{} 2} + ( R / L ) s + 1 / LC ]}{{s}^{{}_{} 2} + ( R / L + {g}_{m} R ) s + ( 1 + {g}_{m} R ) / LC} & ( Equation 4 )\end{matrix}$$

Equation 5 below illustrates how the first complex-zero CTLE circuitry 404 generates a complex-zero that cancels out the complex pole of the VCSEL. For example, Equation 5 sets the complex-zero part of Equation 4 (CTLE gain of first complex-zero CTLE circuitry 404) above equal to the complex-pole part of Equation 2 (the frequency response H_{VCSEL-O}(s) of the optical model 304) above, where the value of the first inductor 508 (L) is equal to the value of the inductance of Lᵥₗ, the value of the first resistor 510 (R) is equal to the resistance of the series resistor Rᵥₗ, and the value of the first capacitor 512 (C) is equal to the capacitance of Cᵥₗ.

$$\\ \begin{matrix}{s}^{{}_{} 2} + ( R / L ) s + 1 / LC = {s}^{{}_{} 2} + ( {R}_{vl} / {L}_{vl} ) s + 1 / {L}_{lv} {C}_{vl} & ( Equation 5 )\end{matrix}$$

In some examples, the first complex-zero CTLE circuitry 404 achieves a complex-zero at the frequency of the complex pole by achieving the same resonance frequency as the resonance frequency of the VCSEL (e.g., by equating 1/LC to 1/LᵥₗCᵥₗ) and the same gain peaking as the gain peaking of the VCSEL (e.g., by equating R/L to Rᵥₗ/Lᵥₗ). In some examples, a transconductance (gₘ) value of the first transistor 506 is selected to push the complex pole of the VCSEL to a higher frequency. For example, a higher transconductance (gₘ) value of the first transistor 506 can achieve a positive second order roll-off (e.g., +40 db/decade amplitude roll-off) to equalize the negative second order roll-off (e.g., −40 dB/decade roll-off) of the VCSEL and, thus, move the complex pole from a lower frequency (e.g., such as a frequency in the frequency band) to a higher frequency (e.g., such as a frequency outside of the frequency band). An example of the complex-zero CTLE frequency response and the VCSEL frequency response is described in further detail below in connection with FIG. 6.

FIG. 6 is an example frequency response graph 600 depicting example optical VCSEL frequency responses 602, 604 across VCSEL bias, an example conventional CTLE response 606, and an example complex-zero CTLE response 608.

In FIG. 6, the example optical VCSEL frequency responses 602 and 604 are frequency responses of the optical portion (e.g., optical model 304 of FIG. 3) of a VCSEL (e.g., the simplified VCSEL model 300 of FIG. 3) across different bias voltages. For example, the optical VCSEL frequency response 602 is the frequency response of the VCSEL at a first VCSEL bias current and the optical VCSEL frequency response 604 is the frequency response of the VCSEL at a second VCSEL bias current. In some examples, the optical VCSEL frequency responses 602, 604 are determined by Equation 3 above, where H_{VCSEL-O}(s) corresponds to the optical VCSEL frequency responses 602, 604 of the VCSEL (e.g., the simplified VCSEL model 300 of FIG. 3).

In FIG. 6, the example optical VCSEL frequency responses 602 and 604 are plotted across a VCSEL bias current. For example, a VCSEL is driven by a bias current, where certain bias currents affect the VCSEL in different ways. For example, increasing bias current of the VCSEL improves resonance frequency but also leads to an increase in a damping factor. Therefore, a dependence of the resonance frequency and damping factor on the bias current makes the frequency response of the VCSEL nonlinear. As used herein, a damping factor is a parameter that characterizes an amount of damping to resonance peaks in a frequency response. A high damping factor (e.g., ζ=1) results in a sharper or narrower resonance peak, indicating a faster decay of oscillation, while a low damping factor (e.g., ζ=0) results in a broader resonance peak, indicating a slower decay of oscillation.

In FIG. 6, an amplitude of the VCSEL output (e.g., Pₒᵤₜ 308 of FIG. 3) increases at a particular frequency. For example, the amplitude of the VCSEL output increases at a first frequency f1. In some examples, this increase or peak in amplitude is due to the complex pole pair introduced by the optical part of the VCSEL (e.g., the optical model 304 of FIG. 3). In other words, a complex pole pair exists at a particular frequency (e.g., the first frequency f1), causing the optical VCSEL frequency responses 602, 604 to peak at the particular frequency (e.g., the first frequency f1). In some examples, the amplitude (e.g., gain) of the VCSEL output drops (e.g., decreases) according to a second order roll-off (e.g., a 40 dB/decade slope) after the particular frequency (e.g., after the first frequency f1). For example, the complex pole causes the amplitude of the VCSEL output to increase and then drop off, thereby limiting the bandwidth of the VCSEL. In some examples, if there was a real pole in the VCSEL, as opposed to the complex pole, the optical VCSEL frequency responses 602, 604 would be a flat (e.g., not include a peak in the amplitude) in the frequency band (e.g., at the first frequency f1) and then would roll off. In some examples, group delay of the VCSEL output peaks at the frequency where the complex pole exists. For example, if group delay was plotted across frequency, the group delay would increase at the first frequency (f1). In some examples, this peak in group delay and amplitude is undesirable and, thus, is to be corrected by an equalizer (e.g., a CTLE). For example, the goal of the equalizer is to cause the amplitude of the VCSEL output to flatten out at as high of a frequency as possible.

In FIG. 6, the example conventional CTLE response 606 is a frequency response of a prior CTLE without an inductor coupled to the resistor of an R-C network. In some examples, the prior and/or conventional CTLE without the inductor introduces a real-zero at a particular frequency. For example, the gain of the prior and/or conventional CTLE increases at the first frequency. In some examples, the increase in gain (e.g., the real-zero) is combined with (e.g., added to) the gain of the VCSEL in order to flatten out the frequency response of the VCSEL and, thus, increase the bandwidth of the VCSEL. However, the conventional CTLE does not negate or cancel out the complex pole of the optical VCSEL frequency responses 602 and 604, nor does the conventional CTLE achieve a positive second order roll-off (e.g., +40 db/decade amplitude roll-off) to equalize the negative second order roll-off (e.g., −40 dB/decade roll-off) of the VCSEL.

In FIG. 6, the example complex-zero CTLE response 608 is a frequency response of the first complex-zero CTLE circuitry 404 of FIGS. 4 and 5. The example complex-zero CTLE response 608 depicts a “dip” (e.g., decrease) in the amplitude value at the first frequency (f1). In this example, the “dip” in the complex-zero CTLE response 608 is the complex-zero and is expressed in the brackets of the numerator of Equation 4 above (e.g., [s²+(R/L)s+1/LC]). In FIG. 6, the example complex-zero CTLE response 608 increases at a second frequency (f2). This increase of the example complex-zero CTLE response 608 illustrates the positive second order roll-off (e.g., +40 db/decade amplitude roll-off) provided by the example first complex-zero CTLE circuitry 404 at the same frequency that the VCSEL generates a negative second order roll-off (e.g., −40 db/decade amplitude roll-off). In FIG. 6, the complex-zero is placed at the same frequency (f1) as the complex pole so that the gain of the VCSEL output and, thus, the bandwidth of the VCSEL, will increase as desired.

FIG. 7 is a schematic illustration of example second complex-zero CTLE circuitry 700. In some examples, the second complex-zero CTLE circuitry 700 is equalizer circuitry, an equalizer circuit, etc. In FIG. 7, the example second complex-zero CTLE circuitry 700 is a reconfigurable CTLE, where values of electrical components (e.g., the first inductor 508, the first resistor 510, and the first capacitor 512 of FIG. 5) can be adjusted and/or tuned for a desired CTLE implementation. In some examples, the first complex-zero CTLE circuitry 404 of FIGS. 4 and 5 are implemented by the second complex-zero CTLE circuitry 700. In some examples, the second complex-zero CTLE circuitry 700 facilitates an application of the first complex-zero CTLE circuitry 404 across a wide range of VCSEL biasing conditions and different VCSEL devices. For example, different VCSEL bias currents cause different VCSEL frequency responses and, thus, move the placement of (e.g., the frequency of) the complex pole pair present in the VCSEL frequency response. As such, the first complex-zero CTLE circuitry 404 of FIGS. 4 and 5 is to be tuned and/or adjusted to accommodate for the change in placement of the complex pole pair. For example, the second complex-zero CTLE circuitry 700 can change the resonance frequency (ωₙ) and damping factor (ζ) of the complex-zero in order to move the complex-zero to a location (e.g., a frequency value) that accurately cancels out the complex pole when the VCSEL bias current changes.

In FIG. 7, the example second complex-zero CTLE circuitry 700 includes an example second transistor 702, an example second inductor (L₁) 704, an example third transistor (R_{CTLE}) 706, an example second capacitor 708, an example second resistor (R_{C}) 710, an example first load 712, an example second load 714, an example fourth transistor (R₂ₐ) 716, an example fifth transistor (R_{2b}) 718, an example third inductor (L₂ₐ) 720, and an example fourth inductor (L_{2b}).

In FIG. 7, the example second transistor 702 is an NMOS transistor and may be implemented by, or implement, the first transistor 506 of FIG. 5. Additionally and/or alternatively, the example second transistor 702 may be any type of transistor, such as a bipolar junction transistor (BJT), field-effect transistors (FETs), insulated-gate bipolar transistors (IGBTs), etc. The example second transistor 702 includes a gate terminal, a drain terminal, and a source terminal. The gate terminal of the second transistor 702 is coupled to an input (Vᵢₙ) (e.g., Vᵢₙ 502). The drain terminal of the example second transistor 702 is coupled to the example first load 712 at a first node 701. The source terminal of the second transistor 702 is coupled to the example second inductor (L₁) 704 and the example second capacitor 708 at a second node 703.

In FIG. 7, the example third transistor (R_{CTLE}) 706 is an NMOS transistor and is used to implement the example first resistor 510 of FIG. 5. For example, a MOSFET (e.g., an NMOS, a PMOS, a CMOS, etc.) can be used as a variable resistor. A MOSFET (Metal-Oxide-Semiconductor Field-Effect Transistor) can act as a variable resistor by operating in its linear region, known as the triode region or the ohmic region. In this region, the MOSFET behaves like a voltage-controlled resistor, and its resistance can be adjusted by changing the gate-source voltage (V_{GS}). For example, increasing Vas decreases the resistance, while reducing V_{GS} increases the resistance. Additionally and/or alternatively, the example third transistor (R_{CTLE}) 706 may be any type of transistor, such as a bipolar junction transistor (BJT), field-effect transistors (FETs), insulated-gate bipolar transistors (IGBTs), etc.

The example third transistor (R_{CTLE}) 706 includes a gate terminal, a drain terminal, and a source terminal. The gate terminal of the third transistor (R_{CTLE}) 706 is coupled to a first voltage input (VDAC1). The source terminal of the third transistor (R_{CTLE}) 706 is coupled to ground. The drain terminal of the example third transistor (R_{CTLE}) 706 is coupled to the example second inductor (L₁) 704.

In FIG. 7, the example second capacitor 708 is a digitally controlled capacitor. In some examples, the second capacitor 708 is one or more digitally controlled capacitors. A digitally controlled capacitor is a type of capacitor that can be selectively switched on or off in discrete steps using digital control signals. A digitally controlled capacitor, such as the example second capacitor 708, provides a means of adjusting the capacitance value in a circuit digitally. The example second capacitor 708 is coupled to the example second resistor (R_{C}) 710.

In FIG. 7, the example first load 712 is a first type of load network for the example second complex-zero CTLE circuitry 700. The example first load 712 includes an example sixth transistor 724 and an example fifth inductor (Lₛₑᵣ) 726.

In FIG. 7, the example sixth transistor 724 is a diode connected PMOS transistor. A diode connected PMOS transistor refers to a configuration where the drain and gate terminals of the PMOS transistor are shorted together, effectively creating a diode-like behavior. For example, the sixth transistor 724 includes a gate terminal, a drain terminal, and a source terminal. The gate terminal of the example sixth transistor 724 is coupled to the drain terminal of the example sixth transistor 724. In some examples, diode connected PMOS transistors are used in bias networks because they always operate in the saturation region (e.g., fully turned on state). For example, a voltage of the gate terminal (V_{G}) is always approximately equal to a voltage at the drain terminal (V_{D}) (e.g., V_{G}=V_{D}) and, thus, a voltage between the gate and drain terminal (V_{DG}) is equal to zero (e.g., V_{GD}=0). In some examples, because the voltage between the gate and drain terminal is equal to zero, the gate to source voltage (V_{GS}) is equal to the drain to source voltage (V_{DS}). Therefore, the diode connected PMOS transistor is always operating in the saturation region because the drain to source voltage (V_{DS}) will always be less than the gate to source voltage minus the threshold voltage (V_{TH}) (e.g., V_{DS}>V_{GS}−V_{TH}). Additionally and/or alternatively, the example sixth transistor 724 may be any type of transistor, such as a bipolar junction transistor (BJT), field-effect transistors (FETs), insulated-gate bipolar transistors (IGBTs), etc.

In FIG. 7, the example fifth inductor (Lₛₑᵣ) 726 is a series peaking inductor. In some examples, a series peaking inductor is used to extend bandwidth of an amplifier, causing a resonance peak in the frequency response. The example fifth inductor (Lₛₑᵣ) 726 is coupled to the drain terminal of the example second transistor 702 at the first node 701 and to the drain terminal of the example sixth transistor 724 at the first node 701. The example fifth inductor (Lₛₑᵣ) 726 is coupled in series to the output (e.g., Vₒᵤₜ 504 of FIG. 5) of the example second complex-zero CTLE circuitry 700.

In FIG. 7, the example second load 714 is a second type of load network for the example second complex-zero CTLE circuitry 700. For example, the second load 714 can be implemented as an alternate load relative to the first load 712. The example second load 714 includes an example seventh transistor 728, an example sixth inductor (Lₛₕᵤₙₜ) 730, an example third resistor (R_{L}) 732, an example eighth transistor 734, and an example ninth transistor 736.

In FIG. 7, the example seventh transistor 728 and the example eighth transistor 734 are PMOS transistors. The example ninth transistor 736 is an example NMOS transistor. The example seventh transistor 728 includes a gate terminal, a drain terminal, and a source terminal. The gate terminal of the example seventh transistor 728 is coupled to a bias voltage source. The source terminal of the example seventh transistor 728 is coupled to a supply voltage source (V_{DD}). The drain terminal of the example seventh transistor 728 is coupled to the example sixth inductor (Lₛₕᵤₙₜ) 730 and coupled to the example third resistor (R_{L}) 732 at the first node 701.

In FIG. 7, the example eighth transistor 734 includes a gate terminal, a drain terminal, and a source terminal. The example ninth transistor 736 includes a gate terminal, a drain terminal, and a source terminal. The gate terminal of the example eighth transistor 734 is shorted to gate terminal of the example ninth transistor 736 at a third node 705. The drain terminal of the example eighth transistor 734 is coupled to the drain terminal of the example ninth transistor 736. The source terminal of the example eighth transistor 734 is coupled to the supply voltage source (V_{DD}) and the source of the example ninth transistor 736 is coupled to ground. In FIG. 7, the configuration of the example eighth transistor 734 and the example ninth transistor 736 form a complimentary metal-oxide-semiconductor (CMOS) inverter. In some examples, a CMOS inverter is used to improve the gain of a common source amplifier (e.g., the gain of the second complex-zero CTLE circuitry 700). In this example, the shorted drain terminals of the eighth transistor 734 and the ninth transistor 736 are the output of the CMOS inverter and, thus, the output of the second complex-zero CTLE circuitry 700. In this example, the shorted gate terminals of the eighth transistor 734 and the ninth transistor 736 are the input of the CMOS inverter.

In FIG. 7, the example third resistor (R_{L}) 732 is a feedback resistor. For example, the third resistor (R_{L}) 732 provides resistive feedback to the CMOS inverter (e.g., the configuration of the eighth transistor 734 and the ninth transistor 736). The third resistor (R_{L}) 732 is coupled to the drain terminal of the seventh transistor 728 and to the drain terminal of the second transistor 702 at the first node 701, and the third resistor (R_{L}) 732 is coupled to the drain terminals of the eighth transistor 734 and the ninth transistor 736 (e.g., the third resistor (R_{L}) 732 is coupled to the output of the CMOS inverter). In FIG. 7, the example third resistor (R_{L}) 732 provides resistive feedback to the CMOS inverter via the example sixth inductor (Lₛₕᵤₙₜ) 730.

In FIG. 7, the example sixth inductor (Lₛₕᵤₙₜ) 730 is a shunt peaking inductor and is coupled between the gate terminals of the eighth transistor 734 and the ninth transistor 736 (e.g., the sixth inductor (Lₛₕᵤₙₜ) 730 is coupled the input of the CMOS inverter) and the drain terminals of the second transistor 702 and the seventh transistor 728. Shunt peaking is a bandwidth extension technique, where the inductor is implemented to extend the bandwidth of the frequency response.

In FIG. 7, the example second complex-zero CTLE circuitry 700 can implement either the first load 712 or the second load 714. In some examples, each load 712, 714 provides different boundaries for different applications of the second complex-zero CTLE circuitry 700. For example, the first load 712 may provide the second complex-zero CTLE circuitry 700 with a different bandwidth than the second load 714.

In FIG. 7, the example second complex-zero CTLE circuitry 700 includes the example fourth transistor (R₂ₐ) 716 and the example fifth transistor (R_{2b}) 718 to tune an example coupled inductor network 738. In FIG. 7, the example fourth transistor (R₂ₐ) 716 and the example fifth transistor (R_{2b}) 718 are voltage-controlled resistors. In some examples, the fourth transistor (R₂ₐ) 716 and the fifth transistor (R_{2b}) 718 are NMOS transistors. Additionally or alternatively, the example fourth transistor (R₂ₐ) 716 and the example fifth transistor (R_{2b}) 718 can be any type of transistor. In FIG. 7, the example coupled inductor network 738 includes the example second inductor (L₁) 704, the example third inductor (L₂ₐ) 720, and the example fourth inductor (L_{2b}) 722.

In FIG. 7, the example fourth transistor (R₂ₐ) 716 includes a gate terminal, a drain terminal, and a source terminal and the example fifth transistor (R_{2b}) 718 includes a gate terminal, a drain terminal, and a source terminal. The example second inductor (L₁) 704 includes a first inductor terminal (p1) and a second inductor terminal (p2). The example third inductor (L₂ₐ) 720 includes a third inductor terminal (p3) and a fourth inductor terminal (p4). The example fourth inductor (L_{2b}) 722 includes a fifth inductor terminal (p5) and a sixth inductor terminal (p6).

The gate terminal of the example fourth transistor (R₂ₐ) 716 is coupled to a second voltage input (VDAC2), the drain terminal of the example fourth transistor (R₂ₐ) 716 is coupled to the fourth inductor terminal (p4) of the example third inductor (L₂ₐ) 720, and the source terminal of the example fourth transistor (R₂ₐ) 716 is coupled to ground. The gate terminal of the example fifth transistor (R_{2b}) 718 is coupled to a third voltage input (VDAC3), the drain terminal of the example fifth transistor (R_{2b}) 718 is coupled to the sixth inductor terminal (p6) of the example fourth inductor (L_{2b}) 722, and the source terminal of the example fifth transistor (R_{2b}) 718 is coupled to ground. In this example, the third inductor terminal (p3) of the third inductor (L₂ₐ) 720 is coupled to ground and the fifth inductor terminal (p5) of the fourth inductor (L_{2b}) 722 is coupled to ground.

In some examples, the second voltage input (VDAC2) and the third voltage input (VDAC3) are control signals to control the inductance of the second complex-zero CTLE circuitry 700. For example, the second voltage input (VDAC) controls whether the fourth transistor (R₂ₐ) 716 is on and inducing a current in the third inductor (L₂ₐ) 720 or whether the fourth transistor (R₂ₐ) 716 is off, causing the third inductor (L₂ₐ) 720 to release any stored energy. In some examples, the third voltage input (VDAC3) controls whether the fifth transistor (R_{2b}) 718 is on and inducing a current in the fourth inductor (L_{2b}) 722 or whether the fifth transistor (R₂ₐ) 716 is off, causing the fourth inductor (L_{2b}) 722 to release any stored energy.

The example second complex-zero CTLE circuitry 700 implements at least three tuning mechanisms to achieve a desired resonance frequency (ωₙ) and damping factor (ζ). Additionally and/or alternatively, the example second complex-zero CTLE circuitry 700 could implement any number of tuning mechanisms in order to achieve the desired resonance frequency (ωₙ) and damping factor (ζ). An example first tuning mechanism of the example second complex-zero CTLE circuitry 700 is the adjustment of the capacitance of the example second capacitor 708. For example, adjusting the capacitance of the second capacitor 708 can facilitate a complex-zero over a wide range frequencies.

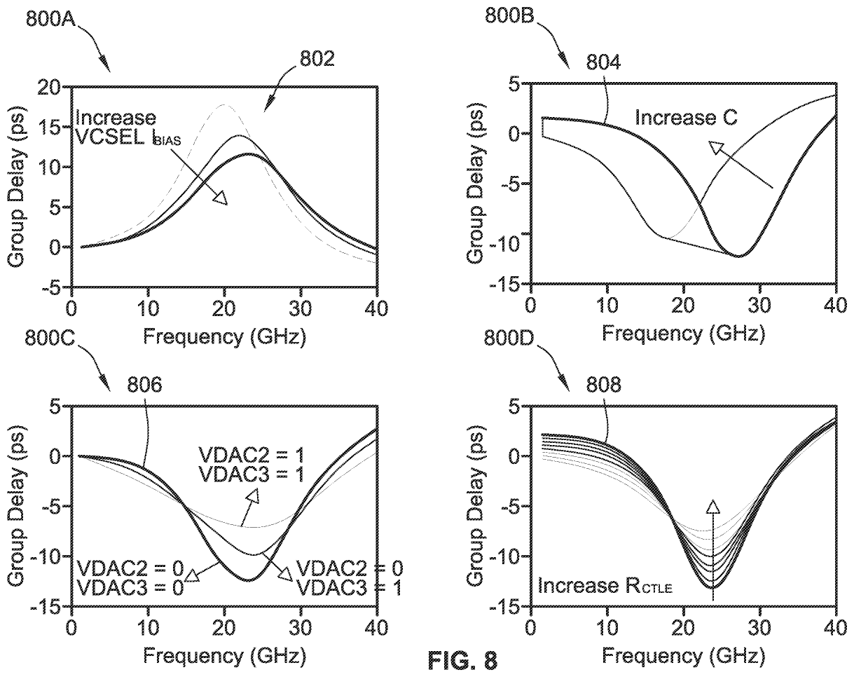

For example, briefly turning to FIG. 8, an example first VCSEL group delay response graph 800A, an example first CTLE response graph 800B, an example second CTLE response graph 800C, and an example third CTLE response graph 800D are shown. The example first VCSEL group delay response graph 800A depicts various first group delay responses 802 of the VCSEL based on an increase in VCSEL bias current. For example, as the bias current of the VCSEL increases, the group delay distortion at the complex pole frequency decreases.

In FIG. 8, the example first CTLE response graph 800B depicts a second group delay response 804 of the second complex-zero CTLE circuitry 700 plotted over frequency. In the example first CTLE response graph 800B, the value of the second group delay response 804 varies based on how the capacitance of the example second capacitor 708 is increased or decreased. For example, the group delay of the second complex-zero CTLE circuitry 700 decreases at lower frequencies when the capacitance of the second capacitor 708 increases. In some examples, the group delay of the second complex-zero CTLE circuitry 700 decreases at higher frequencies when the capacitance of the second capacitor 708 decreases.

Returning to FIG. 7, an example second tuning mechanism of the example second complex-zero CTLE circuitry 700 includes adjusting the inductance of the example coupled inductor network 738. In some examples, the fourth transistor (R₂ₐ) 716 and the fifth transistor (R_{2b}) 718 adjust the inductance of (e.g., tune) the coupled inductor network 738 when the VCSEL is biased with a low current. For example, the second complex-zero CTLE circuitry 700 is to generate a low resonance frequency (ωₙ) and a low damping factor (ζ) in order to equalize (e.g., insert a complex-zero in the same frequency as the complex pole) a VCSEL output that biased with a low VCSEL bias current. In such an example, the fourth transistor (R₂ₐ) 716 and the fifth transistor (R_{2b}) 718 are coupled to the third inductor (L₂ₐ) 720 and the fourth inductor (L_{2b}) 722 (e.g., two secondary coils of the coupled inductor network 738) to change the inductance value of the coupled inductor network 738. For example, switching the high-low states of the fourth transistor (R₂ₐ) 716 and the fifth transistor (R_{2b}) 718 changes the effective inductance value in the second complex-zero CTLE circuitry 700. In some examples, when either the fourth transistor (R₂ₐ) 716 and/or the fifth transistor (R_{2b}) 718 are turned on, the inductance of the primary coil (e.g., the second inductor (L₁) 704 reduces because there will be some current through the third inductor (L₂ₐ) 720 and/or the fourth inductor (L_{2b}), respectively. For example, when the fourth transistor (R₂ₐ) 716 is turned on, there will be current through the third inductor (L₂ₐ) 720, which effects (e.g., reduces) the inductance of the second inductor (L₁) 704. In some examples, when the fourth transistor (R₂ₐ) 716 and the fifth transistor (R_{2b}) 718 are turned off, the inductance of the second inductor (L₁) is high. As such, the example second complex-zero CTLE circuitry 700 can be tuned, and a lower damping factor (ζ) can be achieved at a lower resonance frequency (ωₙ). The tuning of the example coupled inductor network 738 is described in further detail below in connection with FIG. 8C.

For example, briefly turning to FIG. 8C, an example second CTLE response graph 800C is shown. The example second CTLE response graph 800C depicts a third group delay 806 of the second complex-zero CTLE circuitry 700 plotted over frequency. In the example second CTLE response graph 800C, the value of the third group delay 806 varies based on the high and low states of the example third transistor (R₂ₐ) 716 and the example fourth transistor (R_{2b}) 718. In some examples, changing the inductance of the CTLE (e.g., second complex-zero CTLE circuitry 700) for a low VCSEL bias current changes the resonance frequency (ωₙ) and the damping factor (ζ). For example, as shown in the second CTLE response graph 800C, the resonance frequency (ωₙ) of the third group delay 806 is low and the damping factor (ζ) is low when the third transistor (R₂ₐ) 716 and the example fourth transistor (R_{2b}) 718 are both operating in a high state (e.g., when both transistors 716 and 718 are turned on due to VDAC2=1 and VDAC3=1). In some examples, when the fourth transistor (R_{2b}) 718 is operating in a high state (e.g., VDAC3=1) and the third transistor (R₂ₐ) 716 is operating in a low state (e.g., VDAC2=0), the resonance frequency (ωₙ) of the third group delay 806 is lesser than the resonance frequency (ωₙ) when both transistors 716, 718 were operating in a high state. In some examples, when the third transistor (R₂ₐ) 716 and the fourth transistor (R_{2b}) 718 are operating in a low state (e.g., VDAC2=0 and VDAC3=0), the resonance frequency (ωₙ) of the third group delay 806 is lesser than the resonance frequency (ωₙ) when both transistors 716, 718 were operating in a high state and when one transistor (e.g., R_{2b} 718) was operating in a high state (e.g., VDAC3=1).

Returning to FIG. 7, an example third tuning mechanism of the example second complex-zero CTLE circuitry 700 includes adjusting the resistance of the example third transistor (R_{CTLE}) 706. In the example third tuning mechanism, the example second complex-zero CTLE circuitry 700 tunes (e.g., adjusts, increases, decreases, etc.) the resistance of the example third transistor (R_{CTLE}) 706 with the example coupled inductor network 738 to adjust the amount of peaking in the CTLE response.

For example, briefly turning to FIG. 8D, an example third CTLE response graph 800D is shown. The example third CTLE response graph 800D depicts a fourth group delay 808 of the second complex-zero CTLE circuitry 700 plotted over frequency. As shown in FIG. 800D, the damping factor (ζ) can be increased by increasing the R_{CTLE} value. For example, the fourth group delay 808 has a higher group delay value (e.g., picoseconds) when the resistance of the example third transistor (R_{CTLE}) 706 increases. Alternatively, the fourth group delay 808 has a lower group delay value (e.g., picoseconds) when the resistance of the example third transistor (R_{CTLE}) 706 is decreased.

Returning to FIG. 7, the tuning schemes of the example second complex-zero CTLE circuitry 700 can equalize a wide range of VCSEL optical responses having a resonance frequency ranging from a first frequency (e.g., ωₙ=18 GHz) to a second frequency (e.g., ωₙ=28 GHz) and a damping factor ranging from a first damping factor (e.g., ζ=0.35) to a second damping factor (e.g., ζ=0.55).

FIG. 7 includes an example coupled inductor implementation 740 of the example coupled inductor network 738. In some examples, the coupled inductor implementation 740 illustrates a layout of the coupled inductor network 738 on a chip (e.g., a microchip, a computer chip, an integrated circuit, semiconductor material, etc.).

In FIG. 7, the example coupled inductor implementation 740 includes the first inductor terminal (p1), the second inductor terminal (p2), the third inductor terminal (p3), the fourth inductor terminal (p4), the fifth inductor terminal (p5), and the sixth inductor terminal (p6). In some examples, the third inductor terminal (p3) is coupled to the fourth inductor terminal (p4) at a fourth node 707 and the fifth inductor terminal (p5) is coupled to the sixth inductor terminal (p6) at a fifth node 709.

In FIG. 7, the example first inductor terminal (p1) is coupled to the drain terminal of the example third transistor (R_{CTLE}) 706 and the example second inductor terminal (p2) is coupled to the source terminal of the example second transistor 702. In some examples, the third inductor terminal (p3) is grounded and the fourth inductor terminal (p4) is coupled to the drain terminal of the example fourth transistor (R₂ₐ) 716. In some examples, the fifth inductor terminal (p5) is grounded and the sixth inductor terminal (p6) is coupled to the drain terminal of the fifth transistor (R_{2b}) 718.

In some examples, the layout of the coupled inductor implementation 740 is designed to maximize an overlap of secondary coils (third inductor (L₂ₐ) 720 and the fourth inductor (L_{2b}) 722) to the primary coil (the second inductor (L₁) 704) while having no overlap between the two secondary coils. For example, 50% of the primary coil overlaps with one of the secondary coils and the other 50% of the primary coil overlaps with the other secondary coil. In some examples, such a layout ensures the highest primary-to-secondary coil coupling (e.g., coupling coefficient) and, thus, maximizes the tuning range of the second complex-zero CTLE circuitry 700.

In some examples, the second complex-zero CTLE circuitry 700 is implemented by complementary metal-oxide semiconductor (CMOS) technology. In some examples, CMOS technology provides an availability of more than five metal layers in an integrated circuit (IC) or chip. Having multiple metal layers in a CMOS system provides interconnectivity between different components and circuit elements on the IC. These metal layers, also known as metal interconnect layers or metal routing layers, enable the routing of electrical signals between transistors, resistors, capacitors, and other components. In some examples, the coupled inductor network 738 and/or the coupled inductor implementation 740 may be implemented within the top two metal layers of a CMOS stack.

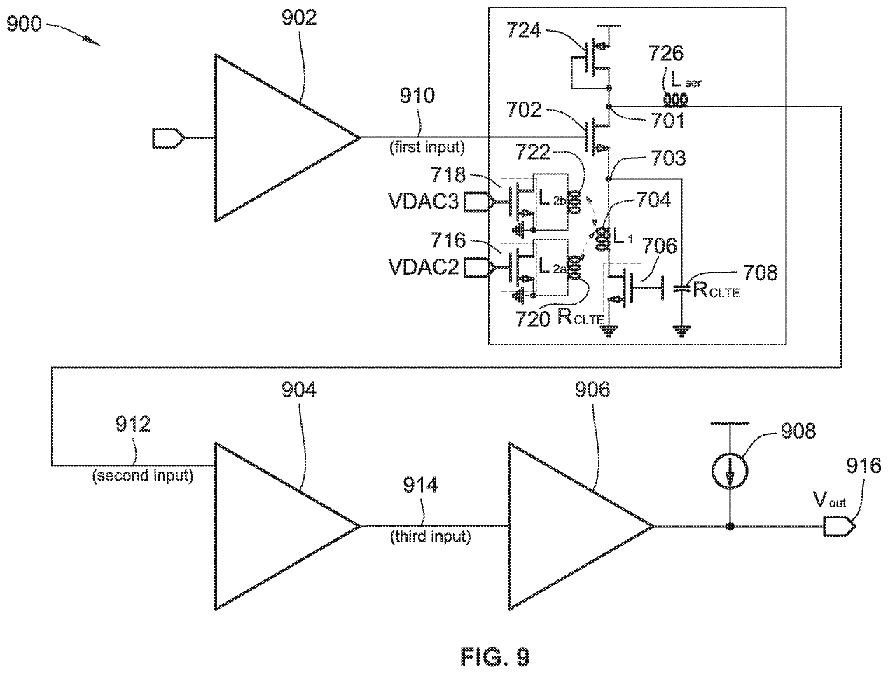

FIG. 9 is an example system diagram of an example VCSEL driver 900 including the example second complex-zero CTLE circuitry 700 of FIG. 7. The example VCSEL driver 900 includes an example input stage 902, the example second complex-zero CTLE circuitry 700 (FIG. 7), an example gain stage 904, an example output stage 906, and example biasing circuitry 908.

In FIG. 9, the example second complex-zero CTLE circuitry 700 includes the example second transistor 702, the example second inductor (L₁) 704, the example third transistor (R_{CTLE}) 706, the example second capacitor 708, the example first load 712, the example fourth transistor (R₂ₐ) 716, the example fifth transistor (R_{2b}) 718, the example third inductor (L₂ₐ) 720, and the example fourth inductor (L_{2b}). The example first load 712 includes the example sixth transistor 724 and the example fifth inductor (Lₛₑᵣ) 726.

In FIG. 9, the example input stage 902 is configured to receive an input voltage (Vᵢₙ). An output of the example input stage 902 is coupled to an input of the example second complex-zero CTLE circuitry 700 and provides an example first input 910 to the example second complex-zero CTLE circuitry 700. An output of the example second complex-zero CTLE circuitry 700 is coupled to an input of the example gain stage 904 and provides an example second input 912 to the example gain stage 904. An output of the example gain stage 904 is coupled to an input of the example output stage 906 and provides an example third input 914 to the example output stage 906. An output of the example output stage 906 is biased by the example VCSEL biasing circuitry 908 and provides an output signal (Vₒᵤₜ) 916 to an example VCSEL (not shown).

In FIG. 9, the gate terminal of the second transistor 702 is coupled to the example first input 910. The drain terminal of the example second transistor 702 is coupled to the example first load 712 at the first node 701. The source terminal of the second transistor 702 is coupled to the example second inductor (L₁) 704 and the example second capacitor (C_{CTLE}) 708 at the second node 703. The gate terminal of the third transistor (R_{CTLE}) 706 is coupled to a first voltage input (VDAC1). The source terminal of the third transistor (R_{CTLE}) 706 is coupled to ground. The drain terminal of the example third transistor (R_{CTLE}) 706 is coupled to the example second inductor (L₁) 704. The gate terminal of the example sixth transistor 724 is coupled to the drain terminal of the example sixth transistor 724 at the first node 701. The example fifth inductor (Lₛₑᵣ) 726 is coupled to the drain terminal of the example second transistor 702 at the first node 701 and to the drain terminal of the example sixth transistor 724 at the first node 701. The example fifth inductor (Lₛₑᵣ) 726 is coupled to the input of the example gain stage 904 and provide the example second input 912 to the example gain stage 904. The gate terminal of the example fourth transistor (R₂ₐ) 716 is coupled to a second voltage input (VDAC2), the drain terminal of the example fourth transistor (R₂ₐ) 716 is coupled to the fourth inductor terminal of the example third inductor (L₂ₐ) 720, and the source terminal of the example fourth transistor (R₂ₐ) 716 is coupled to ground. The gate terminal of the example fifth transistor (R_{2b}) 718 is coupled to a third voltage input (VDAC3), the drain terminal of the example fifth transistor (R_{2b}) 718 is coupled to the sixth inductor terminal of the example fourth inductor (L_{2b}) 722, and the source terminal of the example fifth transistor (R_{2b}) 718 is coupled to ground.

The example VCSEL driver 900 includes the example input stage 902 to process an input signal (Vᵢₙ). The example input stage 902 can be implemented by any type of input stage circuitry, such as filter circuitry, amplifier circuitry, analog-to-digital converter circuitry (ADC), voltage divider circuitry, comparator circuitry, etc. In some examples, the input stage 902 includes a plurality of operations to ensure that the input signal meets the requirements of VCSEL driver 900. For example, the input stage 902 amplifies, level shifts, and/or filters the input signal. In some examples, the input stage 902 converts the input signal to achieve current modulation of a VCSEL. For example, the input stage 902 may generate a controlled current waveform that corresponds to the desired modulation scheme (e.g., on-off keying (OOK), pulse amplitude modulation (PAM), frequency modulation (FM), etc.). In some examples, the input stage 902 may be implemented by any type of input stage circuitry.

The example VCSEL driver 900 includes the example second complex-zero CTLE circuitry 700 to compensate for the frequency-dependent characteristics of the VCSEL and the optical transmission channel. For example, the second complex-zero CTLE circuitry 700 mitigates the complex pole present in the VCSEL optical response, mitigates attenuation, and mitigates other frequency response variations to improve the signal quality at the output of the VCSEL driver. The example second complex-zero CTLE circuitry 700 is reconfigurable and can be reconfigured to accommodate for any type of VCSEL condition. In some examples, the second complex-zero CTLE circuitry 700 generates a complex-zero at the same frequency where the VCSEL generates a complex pole. In such an example, the second complex-zero CTLE circuitry increases a bandwidth of the VCSEL in order to achieve desired data rates.

The example VCSEL driver 900 includes the example gain stage 904 to amplify the example second input 912. In some examples, the gain stage 904 can be implemented by any type of gain stage circuitry, such as cherry-hooper gain circuitry, common-emitter amplifier circuitry, common-source amplifier circuitry, operational amplifier circuitry, etc. In some examples, the gain stage 904 amplifies the second input 912 to a level that is sufficient to achieve the necessary drive current for the VCSEL. In some examples, the gain stage 904 provides amplification while maintaining low distortion and high linearity.

The example VCSEL driver 900 includes the example output stage 906 to send a current modulated signal (e.g., Vₒᵤₜ 916) to the VCSEL. In some examples, the output stage 906 interfaces with the VCSEL, providing the final electrical drive to the laser diode of the VCSEL. In some examples, the output stage 906 may include impedance matching networks to maximize power transfer and ensure efficient operation. In some examples, the output stage 906 may also incorporate protection circuitry to safeguard the VCSEL and the VCSEL driver 900 against overcurrent, overvoltage, and other potential hazards. The example output stage 906 can be implemented by any output stage circuitry, such as impedance matching circuitry, current sink circuitry, push-pull circuitry, H-bridge circuitry, etc.

The example VCSEL driver 900 includes the example biasing circuitry 908 to generate a bias current that is to be applied to the laser diode to establish the VCSEL operating point. In some examples, the biasing circuitry 908 generates the bias current to set the operating point of the laser diode (e.g., VCSEL diode) above its threshold current. For example, the threshold current is the minimum current required for the VCSEL diode to start emitting light. By applying a bias current higher than the threshold current, the example biasing circuitry 908 keeps the VCSEL diode in an active state. In some examples, the biasing circuitry 908 establishes the output power of the VCSEL. For example, bias current directly affects the output power of the VCSEL (e.g., as shown in the first VCSEL group delay response graph 800A of FIG. 8). In some examples, the biasing circuitry 908 changes the bias current to control the output power of the VCSEL. The example biasing circuitry 908 may also provide temperature stability and noise and distortion reduction. In some examples, the biasing circuitry 908 can be implemented by a current source and/or any type of current biasing circuitry.

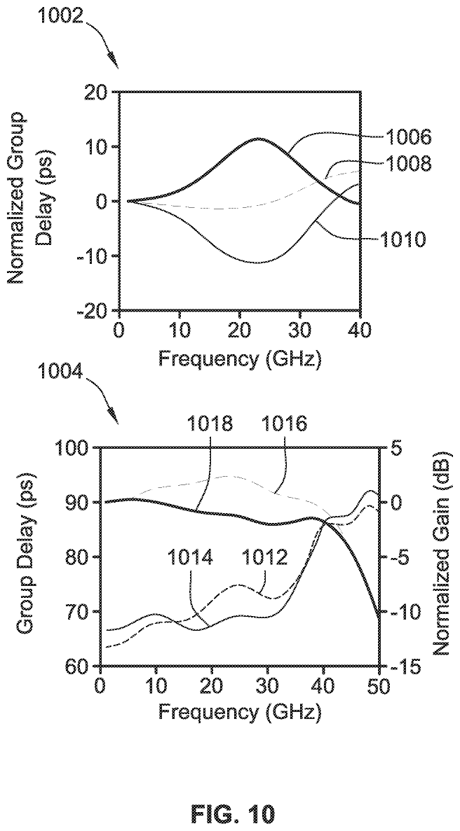

FIG. 10 is an example first group delay response graph 1002 and an example second group delay response graph 1004. The example first group delay response graph 1002 compares an example first normalized group delay response 1006 of a VCSEL, an example second normalized group delay response 1008 of a conventional CTLE, and an example third normalized group delay response 1010 of the second complex-zero CTLE circuitry 700 of FIGS. 7 and 9.

FIG. 10 includes the example first group delay response graph 1002 to show group delay distortion of the VCSEL versus the group delay compensation provided by a conventional CTLE and the second example complex-zero CTLE circuitry 700. For example, in the first group delay response graph 1002, the first normalized group delay response 1006 of the VCSEL illustrates a 12 picosecond group delay distortion at approximately 23 GHz. In some examples, the 23 GHz corresponds to the frequency at which the VCSEL produces a complex pole pair. As shown in the example first group delay response graph 1002, a conventional CTLE compensates for only a portion of the VCSEL group delay distortion. For example, the second normalized group delay response 1008 illustrates that the conventional CTLE has approximately zero seconds of group delay distortion and, thus, cancels out only a portion of the VCSEL group delay distortion. In some examples, the second complex-zero CTLE circuitry 700 compensates for all of the VCSEL group delay distortion by generating a negative group delay response at the frequency corresponding to the complex pole pair (e.g., approximately 23 GHz). For example, the third normalized group delay response 1010 illustrates that the complex-zero CTLE circuitry 700 has approximately a negative 12 picosecond group delay at 23 GHz. Therefore, the example second complex-zero CTLE circuitry 700 cancels the group delay distortion of the VCSEL and bounds the group delay distortion of the VCSEL to below 3 picoseconds.

FIG. 10 includes the example second group delay response graph 1004 to compare group delay and gain of a VCSEL implementing a conventional CTLE versus the group delay and gain of a VCSEL implementing the example second complex-zero CTLE circuitry 700. The example second group delay response graph 1004 includes a first group delay response 1012, a second group delay response 1014, a first gain response 1016, and a second gain response 1018.

In FIG. 10, the example first group delay response 1012 corresponds to the group delay of a VCSEL that implements a conventional CTLE in a VCSEL driver. For example, the first group delay response 1012 illustrates the group delay response of the VCSEL in response to the second normalized group delay response 1008 of the conventional CTLE. For example, the first group delay response 1012 illustrates how much the conventional CTLE cancels out the group delay distortion of the VCSEL.

In FIG. 10, the example second group delay response 1014 corresponds to the group delay of a VCSEL that implements the example VCSEL driver 900 of FIG. 9. For example, the second group delay response 1014 corresponds to a response of the VCSEL when the example second complex-zero CTLE circuitry 700 generates the complex-zero at the complex pole frequency. In some examples, the second group delay response 1014 illustrates the group delay response of the VCSEL in response to the third normalized group delay response 1010 of the second complex-zero CTLE circuitry 700. For example, the negative group delay provided by the second complex-zero CTLE circuitry 700 (as shown by the example third normalized group delay response 1010 in the example first group delay response graph 1002) is added to the positive group delay distortion provided by the VCSEL (as shown by the example first normalized group delay response 1006 in the example first group delay response graph 1002) and, thus, reduces the group delay distortion of the VCSEL.

In FIG. 10, the example first gain response 1016 corresponds to the gain of a VCSEL that implements a conventional CTLE in a VCSEL driver. For example, the first gain response 1016 depicts the gain of the VCSEL having gain peaking (e.g., approximately 2.5 dB of gain peaking in the frequency band).

In FIG. 10, the example second gain response 1018 corresponds to the gain of a VCSEL that implements the example VCSEL driver 900 of FIG. 9. For example, the second gain response 1018 depicts the gain of the VCSEL having no gain peaking and, thus, a flatter gain response.

In some examples, the first group delay response graph 1002 and the second group delay response graph 1004 illustrate an improvement of the VCSEL when the VCSEL implements and/or receives an input signal from a VCSEL driver having the example second complex-zero CTLE circuitry 700. For example, the second complex-zero CTLE circuitry 700 achieves a better VCSEL bandwidth and, thus, better data rate relative to a conventional CTLE.

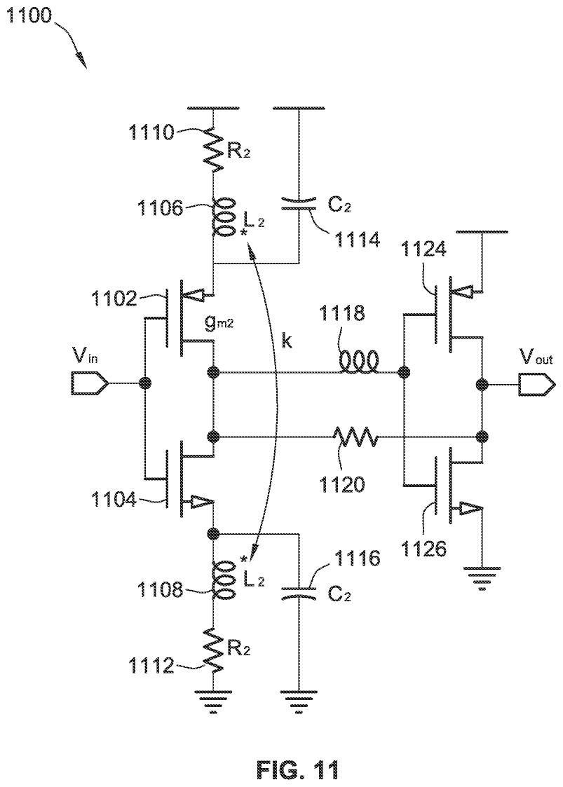

FIG. 11 is a schematic illustration of example third complex-zero CTLE circuitry 1100. The example third complex-zero CTLE circuitry 1100 includes an example tenth transistor 1102, an example eleventh transistor 1104, and example seventh inductor (L₂) 1106, an example eighth inductor (L₂) 1108, an example fourth resistor (R₂) 1110, an example fifth resistor (R₂) 1112, an example third capacitor (C₂) 1114, an example fourth capacitor (C₂) 1116, an example ninth inductor 1118, an example sixth resistor 1120, an example twelfth transistor 1124, and an example thirteenth transistor 1126.

In FIG. 11, the example tenth transistor 1102 is a PMOS transistor and includes a gate terminal, a drain terminal, and a source terminal. The example eleventh transistor 1104 is an NMOS transistor and includes a gate terminal, a drain terminal, and a source terminal. The gate terminals of the example tenth transistor 1102 and the example eleventh transistor 1104 are tied to an input voltage (Vᵢₙ). The drain terminal of the tenth transistor 1102 is coupled to the drain terminal of the eleventh transistor 1104. The source terminal of the example tenth transistor 1102 is coupled to the example seventh inductor 1106 and the source terminal of the example eleventh transistor 1104 is coupled to the example eighth inductor 1108. The example fourth resistor 1110 is coupled to the example seventh inductor 1106 and the example fifth resistor 1112 is coupled to the example eighth inductor 1108. In this example, the fourth resistor 1110 is coupled between the seventh inductor 1106 and a supply voltage, while the fifth resistor 1112 is coupled between the eighth inductor 1108 and ground. The example third capacitor 1114 is coupled to the example seventh inductor 1106 and to the source terminal of the example tenth transistor 1102. The example fourth capacitor 1116 is coupled to the example eighth inductor 1108 and to the source terminal of the example eleventh transistor 1104. In this example, the third capacitor 1114 is coupled between the supply voltage and the source terminal of the tenth transistor 1102, while the fourth capacitor 1116 is coupled between the source terminal of the eleventh transistor 1104 and ground.

In FIG. 11, the example twelfth transistor 1124 is a PMOS transistor and includes a gate terminal, a drain terminal, and a source terminal. The example thirteenth transistor 1126 is an NMOS transistor and includes a gate terminal, a drain terminal, and a source terminal. The example ninth inductor 1118 is coupled to the drain terminals of the example tenth transistor 1102 and the example eleventh transistor 1104 and coupled to the gate terminals of the example twelfth transistor 1124 and the example thirteenth transistor 1126. The example sixth resistor 1120 is coupled to the drain terminals of the example tenth transistor 1102 and the example eleventh transistor 1104 and coupled to the drain terminals of the example twelfth transistor 1124 and the example thirteenth transistor 1126. The drain terminals of the example twelfth transistor 1124 and the example thirteenth transistor 1126 are coupled together. The source terminal of the example twelfth transistor 1124 is coupled to a supply voltage and the source terminal of the example thirteenth transistor 1126 is coupled to ground.

In some examples, the tenth transistor 1102 and the eleventh transistor 1104 form a complementary implementation of the third complex-zero CTLE circuitry 1100. For example, the tenth transistor 1102, the seventh inductor (L₂) 1106, the fourth resistor (R₂) 1110, and the third capacitor (C₂) 1114 are complimentary to the eleventh transistor 1104, the eighth inductor (L₂) 1108, the fifth resistor (R₂) 1112, and the fourth capacitor (C₂) 1116. In a complementary implementation (e.g., a complementary circuit), two types of devices are used: NMOS transistors (e.g., the eleventh transistor 1104) and PMOS transistors (e.g., the tenth transistor 1102), because the NMOS transistor (e.g., the eleventh transistor 1104) and PMOS transistor (e.g., the tenth transistor 1102) have complementary characteristics. For example, NMOS transistors are used for implementing the low-side or ground-connected switches in a circuit while PMOS transistors are used for implementing the high-side or supply-connected switches in the circuit. In some examples, the complementary circuit of the third complex-zero CTLE circuitry 1100 improves linearity of the CTLE and improves the power consumption of the CTLE. For example, a complimentary circuit reduces power consumption because a same bias current is reused between the PMOS transistor and the NMOS transistor to generate double the effective transconductance. Additionally, the complementary circuit of the example third complex-zero CTLE circuitry 1100 reduces the distortion of the CTLE at higher frequencies. For example, the third complex-zero CTLE circuitry 1100 still outputs a desired signal (e.g., still generates a frequency response with a complex-zero at the correct frequency) at higher input frequency.

In the example third complex-zero CTLE circuitry 1100, the example seventh inductor (L₂) 1106 and the example eighth inductor (L₂) 1108 are magnetically coupled. For example, in a printed circuit board (PCB) or chip design, the seventh inductor (L₂) 1106 and the eighth inductor (L₂) 1108 are stacked on top of each other. In some examples, when two inductors are magnetically coupled, it means that there is a shared magnetic field between them. In some examples, magnetic coupling occurs when the magnetic field generated by one inductor (e.g., the seventh inductor 1106) intersects with the windings of the other inductor (e.g., the eighth inductor 1108), resulting in a mutual inductive effect. Mutual inductance is when the changing current in one inductor induces a voltage in the other inductor. In some examples, mutual inductance between the coupled inductors (e.g., the seventh inductor 1106 and the eighth inductor 1108) affects a total inductance of the third complex-zero CTLE circuitry 1100. For example, the mutual inductance adds to the individual inductances and increases the effective inductance.

In some examples, when two inductors are magnetically coupled, they have a coupling coefficient (k). The coupling coefficient is a measure of the magnetic coupling between the inductors and ranges from 0 to 1. A value of 1 indicates perfect coupling, where all the magnetic field lines of one inductor pass through the other inductor's windings. A value of 0 indicates no coupling, where the magnetic field of one inductor does not intersect with the windings of the other. In this example, by coupling the seventh inductor 1106 and the eighth inductor 1108, the area of the third complex-zero CTLE circuitry 1100 is less than the area of an uncoupled inductor. For example, in order for a higher inductance, both the seventh inductor 1106 and the eighth inductor 1108 would need to be double the size. However, the coupled inductor does not have that issue, because the seventh inductor 1106 and the eighth inductor 1108 are stacked, which reduces the area required on the chip for both of the inductors.

In some examples, the third complex-zero CTLE circuitry 1100 can be used to as an alternative equalizer to the example first complex-zero CTLE circuitry 404 or the example second complex-zero CTLE circuitry 700. For example, the third complex-zero CTLE circuitry 1100 can be used when a user wants energy efficiency (e.g., improved power consumption) and linearity (e.g., reduced noise distortion) in an equalizer.

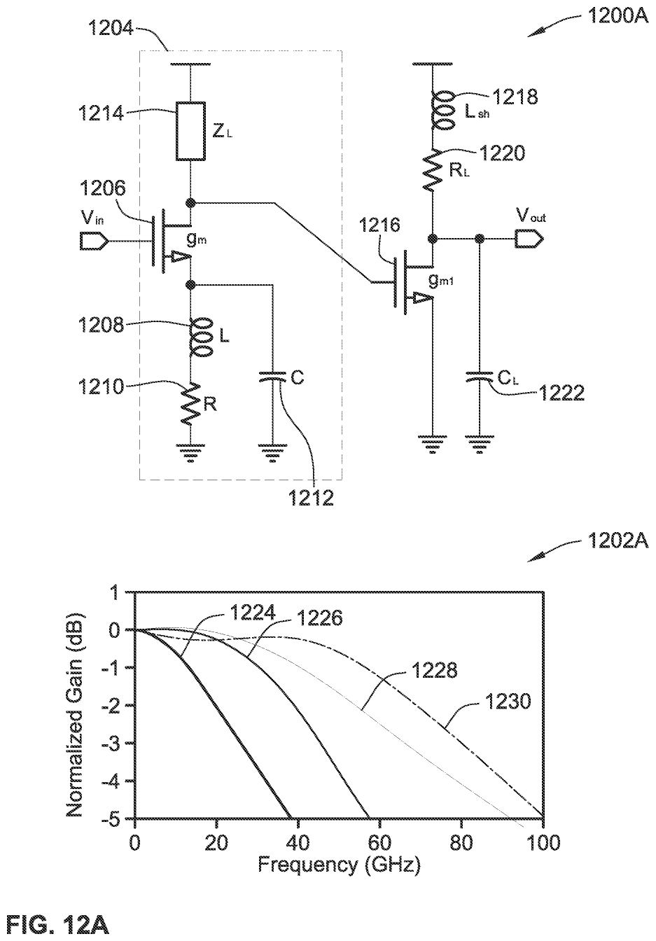

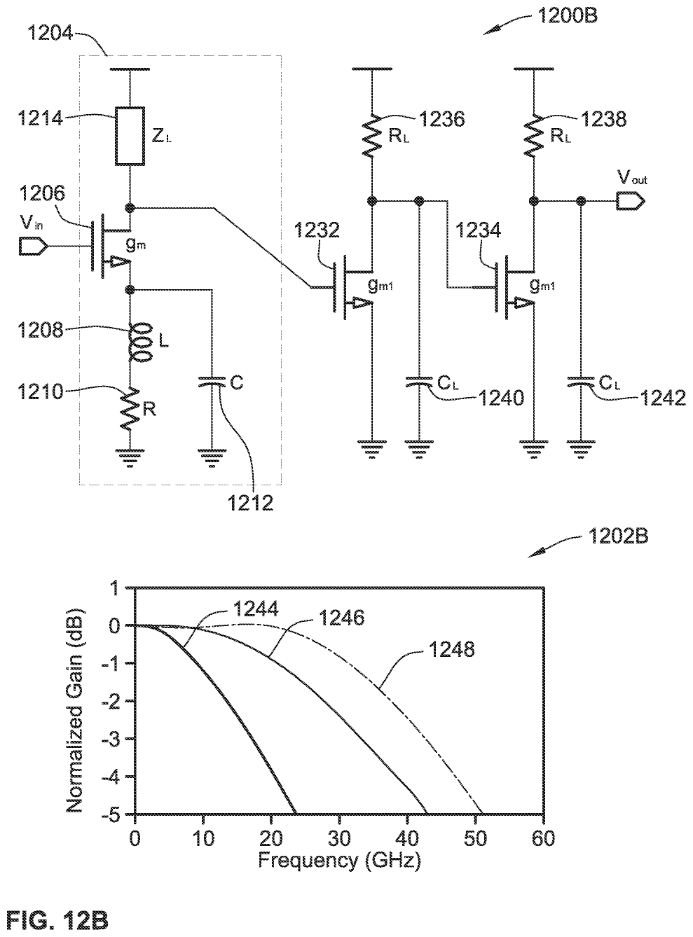

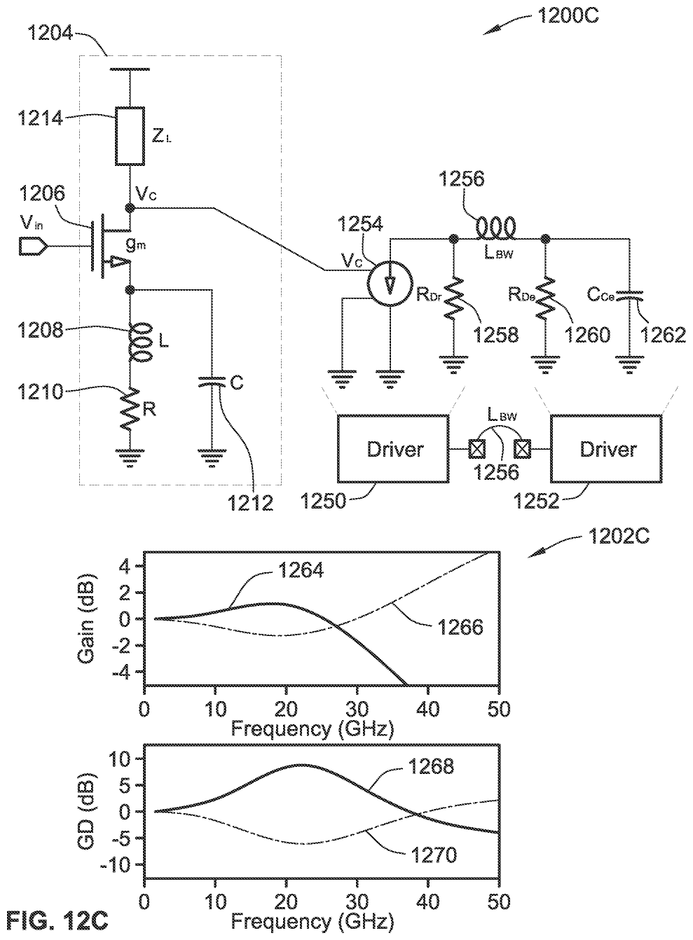

FIGS. 12A, 12B, and 12C are schematic illustrations of different applications of the example first complex-zero CTLE circuitry 404 of FIG. 5. For example, the first complex-zero CTLE circuitry 404 can be widely applied to improve bandwidth of various other wideband systems. As such, the example equalizer circuitry disclosed herein (e.g., first complex-zero CTLE circuitry 404, the second complex-zero CTLE circuitry 700, and the third complex-zero CTLE circuitry 1100) may be coupled to and/or applied to any bandwidth extension system in order to further improve bandwidth of other data communication systems.

FIG. 12A is a schematic illustration of an example first wideband system 1200A and a corresponding example first bandwidth response graph 1202A. FIG. 12B is a schematic illustration of an example second wideband system 1200B and a corresponding example second bandwidth response graph 1202B. FIG. 12C is a schematic illustration of an example third wideband system 1200C and a corresponding example frequency response graph 1202C.

In FIG. 12A, the example first wideband system 1200A includes example fourth complex-zero CTLE circuitry 1204. In some examples, the fourth complex-zero CTLE circuitry 1204 is the first complex-zero CTLE circuitry 404 of FIGS. 4 and 5. The example fourth complex-zero CTLE circuitry 1204 includes example first transistor 1206, an example first inductor 1208, an example first resistor 1210, an example first capacitor 1212, and an example load 1214.

In FIG. 12A, the example first transistor 1206 includes a gate terminal, a drain terminal, and a source terminal. The gate terminal of the example first transistor 1206 is coupled to an input (Vᵢₙ). The drain terminal of the example first transistor 1206 is coupled to example load 1214. The source terminal of the example first transistor 1206 is coupled to a first terminal of the example first inductor 1208 and a first terminal of the example first capacitor 1212. The example first inductor 1208 is coupled between the source terminal of the example first transistor 1206 and the example first resistor 1210. For example, a second terminal of the first inductor 1208 is coupled to the first resistor 1210 while the first terminal of the first inductor 1208 is coupled to the source terminal of the first transistor 1206. The example first resistor 1210 is coupled between the example first inductor 1208 and ground. The first terminal of the example first capacitor 1212 is coupled between the source terminal of the first transistor 1206 and the first terminal of the first inductor 1208, and a second terminal of the first capacitor 1212 is coupled to ground.

In FIG. 12A, the example first wideband system 1200A includes an example fourteenth transistor 1216, an example ninth inductor (Lₛₕ) 1218, an example seventh resistor (R_{L}) 1220, and an example fifth capacitor (C_{L}) 1222. The example fourteenth transistor 1216 includes a gate terminal, a drain terminal, and a source terminal. The gate terminal of the example fourteenth transistor 1216 is coupled to the drain terminal of the example first transistor 1206 and to the example load 1214. The drain terminal of the example fourteenth transistor 1216 is coupled to the example seventh resistor (R_{L}) 1220. The source terminal of the example fourteenth transistor 1216 is coupled to ground. The example seventh resistor (R_{L}) 1220 is coupled to the example ninth inductor (Lₛₕ) 1218. The example fifth capacitor (C_{L}) 1222 is coupled to an output (Vₒᵤₜ). The output (Vₒᵤₜ) is coupled to the drain terminal of the example fourteenth transistor 1216.

In this example, the example fourteenth transistor 1216, the example ninth inductor (Lₛₕ) 1218, the example seventh resistor (R_{L}) 1220, and the example fifth capacitor (C_{L}) 1222 form a shunt peaking circuit. In a shunt peaking circuit, the fourteenth transistor 1216 is to output a load. However, there is some resistance to outputting that load into the fourteenth transistor 1216, and that resistance is represented by seventh resistor (R_{L}) 1220. That resistance (e.g., the seventh resistor (R_{L}) 1220) limits the bandwidth of a system. A shunt inductor (e.g., the ninth inductor (Lₛₕ) 1218) is added to increase the bandwidth. For example, the ninth inductor (Lₛₕ) 1218 provides inductive reactance that boosts the output signal at high frequencies which flattens a frequency response and, thus, extends the bandwidth of the circuit.

For example, the first bandwidth response graph 1202A depicts a first bandwidth 1224, a second bandwidth 1226, a third bandwidth 1228, and a fourth bandwidth 1230. The example first bandwidth 1224, second bandwidth 1226, third bandwidth 1228, and fourth bandwidth 1230 correspond to the gains of the example first wideband system 1200A plotted across frequency. For example, the first bandwidth 1224 corresponds to the gain of the first wideband system 1200A without the ninth inductor (Lₛₕ) 1218 (e.g., without bandwidth extension). The example second bandwidth 1226 corresponds to the gain of the example first wideband system 1200A with the ninth inductor (Lₛₕ) 1218 (e.g., with bandwidth extension by shunt peaking). In some examples, the bandwidth of the first wideband system 1200A implementing the shunt peaking is greater than the bandwidth of the first wideband system 1200A not implementing shunt peaking.

In some examples, adding an equalizer, such as a CTLE, to a wideband system can further increase the bandwidth. For example, the third bandwidth 1228 corresponds to the gain of the first wideband system 1200A implementing both shunt peaking and a conventional CTLE. In some examples, the bandwidth of the first wideband system 1200A implementing both shunt peaking and a conventional CTLE is greater than the bandwidth of the first wideband system 1200A implementing only shunt peaking.

However, the example fourth complex-zero CTLE circuitry 1204 provides a greater extension of bandwidth in the example first wideband system 1200A. For example, the fourth bandwidth 1230 corresponds to the gain of the first wideband system 1200A implementing both the fourth complex-zero CTLE circuitry 1204 and shunt peaking. The fourth bandwidth 1230 of the first wideband system 1200A implementing both the fourth complex-zero CTLE circuitry 1204 and shunt peaking is greater than the first bandwidth 1224, the second bandwidth 1226, and the third bandwidth 1228, as shown in the example first bandwidth response graph 1202A.

FIG. 12B is a schematic illustration of the example second wideband system 1200B including the example fourth complex-zero CTLE circuitry 1204 to equalize a second order roll-off of the example second wideband system 1200B. In some examples, wideband systems with multiple real poles can effectively create higher order gain roll-off. As shown in the example second bandwidth response graph 1202B, the example fourth complex-zero CTLE circuitry 1204, when used in a multi-real-pole system (e.g., the second wideband system 1200B), can perform second-order gain equalization and, thus, extend the bandwidth.

In FIG. 12B, the example second wideband system 1200B has two stages and, thus, creates a second order roll-off. For example, the second wideband system 1200B includes an example fifteenth transistor 1232, an example sixteenth transistor 1234, an example eighth resistor (R_{L}) 1236, an example ninth resistor (R_{L}) 1238, an example sixth capacitor 1240, and an example seventh capacitor 1242.

In FIG. 12B, the example fifteenth transistor 1232 and the example sixteenth transistor 1234 are NMOS transistors and include a gate terminal, a drain terminal, and a source terminal. The gate terminal of the example fifteenth transistor 1232 is coupled to the drain terminal of the first transistor 1206 and coupled to the load 1214. The drain terminal of the example fifteenth transistor 1232 is coupled to the eighth resistor 1236. The source terminal of the example fifteenth transistor 1232 is coupled to ground. The gate terminal of the example sixteenth transistor 1234 is coupled to the drain terminal of the example fifteenth transistor 1232 and coupled to the eighth resistor 1236. The example sixth capacitor 1240 is coupled to the gate terminal of the example sixteenth transistor 1234. The drain terminal of the example sixteenth transistor 1234 is coupled to the ninth resistor 1238. The source terminal of the example sixteenth transistor 1234 is coupled to ground. The example seventh capacitor 1242 is coupled to an output (Vₒᵤₜ) of the example second wideband system 1200B, where the output (Vₒᵤₜ) is coupled to the drain terminal of the example sixteenth transistor 1234.

In some examples, the fifteenth transistor 1232, the eighth resistor 1236, and the sixth capacitor 1240 form a first stage of the second wideband system 1200B. In some examples, the sixteenth transistor 1234, the ninth resistor 1238, and the seventh capacitor 1242 form a second stage of the example second wideband system 1200B. In some examples, the second stage creates the second order roll-off in the second wideband system 1200B. For example, in a second order (e.g., two-stage) wideband system (e.g., the second wideband system 1200B), the gain of the output signal decreases by 40 dB for every decade increase in frequency beyond the cutoff frequency (e.g., the frequency at which the gain response starts to attenuate significantly). The example fourth complex-zero CTLE circuitry 1204 compensates for that decrease in gain and, thus, extends the bandwidth of the second wideband system 1200B.

For example, the second bandwidth response graph 1202B depicts a fifth bandwidth 1244, a sixth bandwidth 1246, and a seventh bandwidth 1248. The example fifth bandwidth 1244, sixth bandwidth 1246, and seventh bandwidth 1248 correspond to gains of the example second wideband system 1200B plotted across frequency. For example, the fifth bandwidth 1244 corresponds to the gain of the second wideband system 1200B without any type of bandwidth extension (e.g., without the second stage). As shown in the second bandwidth response graph 1202B, the fifth bandwidth 1244 is less than 20 GHz. The example sixth bandwidth 1246 corresponds to the gain of the example second wideband system 1200B implementing a conventional CTLE. As shown in the example second bandwidth response graph 1202B, the sixth bandwidth 1246 is approximately 33 GHz. Therefore, the conventional CTLE extended the bandwidth of the example second wideband system 1200B. However, the example fourth complex-zero CTLE circuitry 1204 extends the bandwidth of the example second wideband system 1200B beyond the frequency that the conventional CTLE extends the bandwidth. For example, the seventh bandwidth 1248 corresponds to the gain of the second wideband system 1200B implementing the fourth complex-zero CTLE circuitry 1204. As shown in the example second bandwidth response graph 1202B, the seventh bandwidth 1248 is approximately 45 GHz. Therefore, the example fourth complex-zero CTLE circuitry 1204 extends the bandwidth of the example second wideband system 1200B beyond the frequency extended by the conventional CTLE.

FIG. 12C is a schematic illustration of the example third wideband system 1200C including the example fourth complex-zero CTLE circuitry 1204 to extend the bandwidth of a packaging interface. For example, packaging interfaces are limited by bond wire inductance. As used herein, a bond wire makes a connection between one device to another device in a semiconductor package. For example, when integrated circuits (iCs) or other semiconductor devices are packaged, they typically require wire bonds to connect the internal circuitry to the external leads or pads on the package. As used herein, bond wire inductance is the inductance associated with the wire used for interconnecting electronic components (e.g., devices, integrated circuits, etc.). In some examples, bond wire inductance is a parasitic inductance and can have an impact on the performance of higher frequency package interfaces. For example, the bond wire inductance can limit the bandwidth of the system (e.g., the third wideband system 1200C).

In FIG. 12C, the example third wideband system 1200C represents a packaging interface between an example driver 1250 and an example device 1252, connected by an example bond wire (L_{BW}) 1256. In FIG. 12C, the example driver 1250 is modeled by an example current source 1254 and an example driver resistor (R_{Dr}) 1258. In FIG. 12C, the example device 1252 includes input impedance which is modeled by an example device resistor (R_{De}) 1260 and an example device capacitor (C_{De}) 1262.

In FIG. 12C, the example current source 1254 is coupled to the drain terminal of the example first transistor 1206 and to the example driver resistor 1258. In some examples, the current of the current source 1254 is determined by a driver input voltage (V_{C}). In some examples, the current source 1254 provides current, to driver resistor 1258 and the example device 1252 through the example bond wire (L_{BW}) 1256.

In FIG. 12C, the example device resistor (R_{De}) 1260 is coupled in parallel to the example device capacitor (C_{De}) 1262, forming a parallel R-C network. In some examples, the parallel R-C network models the input impedance of the device 1252. In some examples, at higher frequency, the input impedance of the device 1252 and the bond wire inductance of the bond wire (L_{BW}) 1256 creates a complex pole in the frequency band of the third wideband system 1200C. For example, at a particular in-band frequency, the driver resistor (R_{Dr}) 1258, the bond wire (L_{BW}) 1256, the device resistor (R_{De}) 1260, and the device capacitor (C_{De}) 1262 cause a complex pole in the frequency response of the third wideband system 1200C. The example fourth complex-zero CTLE circuitry 1204 introduces a complex-zero at the particular in-band frequency to negate the effects of the complex pole.

For example, the frequency response graph 1202C depicts gain and group delay, plotted across frequency, of the third wideband system 1200C. The example frequency response graph 1202C includes an example first package response 1264, an example first CTLE package response 1266, an example second package response 1268, and an example second CTLE package response 1270.

In FIG. 12C, the example first package response 1264 depicts gain peaking at a particular frequency (e.g., approximately 20 GHz). In some examples, the gain peaking shown by the first package response 1264 is a location of the complex pole in the third wideband system 1200C. The example first CTLE package response 1266 depicts a gain compensation at the particular frequency (e.g., approximately 20 GHz). For example, the fourth complex-zero CTLE circuitry 1204 generates a complex-zero at the particular frequency to improve the overall frequency response of the third wideband system 1200C.

In FIG. 12C, the example second package response 1268 depicts group delay distortion at a particular frequency (e.g., approximately 20 GHz). In some examples, the group delay distortion (e.g., the peak in group delay shown by the second package response 1268) is the frequency location of the complex pole in the third wideband system 1200C. The example second CTLE package response 1270 depicts a group delay compensation at the particular frequency (e.g., approximately 20 GHz). For example, the fourth complex-zero CTLE circuitry 1204 generates a complex-zero at the particular frequency to improve the overall frequency response of the third wideband system 1200C.

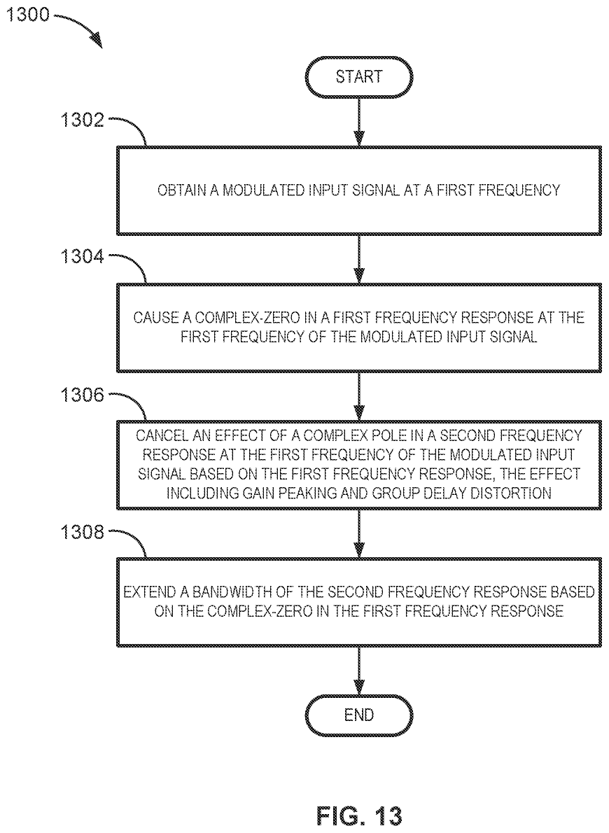

FIG. 13 is a flowchart representative of example operations 1300 of the example first complex-zero CTLE circuitry 404 of FIGS. 4 and 5 to cancel an effect of the complex pole in a frequency response of a wideband system. In some examples, the flowchart of FIG. 13 is representative of example operations 1300 of the example second complex-zero CTLE circuitry 700 of FIG. 7 and/or the example third complex-zero CTLE circuitry 1100 of FIG. 11.

The example operations of FIG. 13 begin at block 1302 when the example first complex-zero CTLE circuitry 404 obtains a modulated input signal at a first frequency. For example, the gate terminal of the first transistor 506 obtains an input voltage (Vᵢₙ) 502 modulated at a first frequency.

The example first complex-zero CTLE circuitry 404 causes a complex-zero in a first frequency response at the first frequency of the modulated input signal (block 1304). For example, the first inductor 508, the first resistor 510, and the first capacitor 512 are implemented by the example first complex-zero CTLE circuitry 404 to introduce a complex-zero in a CTLE frequency response (e.g., the first frequency response) at the first frequency.

The example first complex-zero CTLE circuitry 404 cancels an effect of a complex pole in a second frequency response at the first frequency of the modulated input signal based on the first frequency response, the effect including gain peaking and group delay distortion (block 1306). For example, the first inductor 508, the first resistor 510, and the first capacitor 512 introduce the complex-zero in the CTLE frequency response in order to equalize and/or cancel the effects of a bandwidth system frequency response (e.g., a VCSEL frequency response, a second frequency response, etc.) occurring at the first frequency.

The example first complex-zero CTLE circuitry 404 extends a bandwidth of the second frequency response based on the complex-zero in the first frequency response (1308). For example, the first inductor 508 of the first complex-zero CTLE circuitry 404 achieves a positive (e.g., +40 db/decade) amplitude roll-off to equalize the negative (e.g., −40 dB/decade) roll-off of the VCSEL optical response and, thus, extends the bandwidth of the VCSEL optical response. The operations 1300 end.

From the foregoing, it will be appreciated that example systems, apparatus, articles of manufacture, and methods have been disclosed that equalize a negative effect of a wideband system at certain frequencies. For example, example disclosed herein include an equalizer that generates a complex-zero at a frequency corresponding to a complex pole introduced by a wideband system, where the complex-zero cancels the complex pole. Implementing the equalizer that cancels the complex pole enables the wideband system to operate efficiently and accurately at higher frequencies and a larger bandwidth relative to a wideband system that does not implement such an equalizer. Disclosed systems, apparatus, articles of manufacture, and methods improve the efficiency of using a wideband system by reducing signal distortion and amplitude variation of an output of the wideband system when the wideband system is operating at high frequencies. Disclosed systems, apparatus, articles of manufacture, and methods are accordingly directed to one or more improvement(s) in the operation of a machine such as a computer or other electronic and/or mechanical device.

Example methods and apparatus for complex-zero equalizers are disclosed herein. Further examples and combinations thereof include the following:

Example 1 includes a circuit comprising driver circuitry including a first input, and equalizer circuitry including a second input, a first output coupled to the first input, a transistor including a gate terminal, a drain terminal, and a source terminal, the gate terminal coupled to the second input and the drain terminal coupled to the first output, an inductor including a first inductor terminal and a second inductor terminal, the first inductor terminal coupled to the source terminal of the transistor, a resistor coupled to the second inductor terminal, and a capacitor including a first terminal and a second terminal coupled to the source terminal and to the first inductor terminal and the second terminal coupled to ground.

Example 2 includes the circuit of example 1, wherein the equalizer circuitry further includes a load coupled to the drain terminal of the transistor and coupled to the first output, the load including a series peaking inductor.

Example 3 includes the circuit of example 1, wherein the equalizer circuitry further includes a load coupled to the drain terminal of the transistor and coupled to the first output, the load including a shunt peaking inductor.

Example 4 includes the circuit of example 1, wherein the equalizer circuitry is a continuous time linear equalizer circuit.

Example 5 includes the circuit of example 1, wherein the transistor is an n-channel metal-oxide semiconductor (NMOS) transistor.

Example 6 includes the circuit of example 1, wherein the driver circuitry includes a second output configured to be coupled to a wideband system.

Example 7 includes the circuit of example 6, wherein the wideband system is a vertical cavity surface emitting laser.

Example 8 includes the circuit of example 1, wherein the driver circuitry includes a second output configured to be coupled to a bandwidth extension system.

Example 9 includes the circuit of example 1, wherein the transistor is a first transistor, the inductor is a first inductor, the resistor is a first resistor, and the capacitor is a first capacitor, the gate terminal is a first gate terminal, the drain terminal is a first drain terminal, and the source terminal is a first source terminal, the equalizer circuitry further including a second transistor including a second gate terminal, a second drain terminal, and a second source terminal, the second gate terminal coupled to the second input and the second drain terminal coupled to the first drain terminal of the first transistor and to the first output, a second inductor including a third inductor terminal and a fourth inductor terminal, the third inductor terminal coupled to the second source terminal, a second resistor coupled to the fourth inductor terminal, and a second capacitor coupled to the second source terminal and the third inductor terminal.

Example 10 includes the circuit of example 9, wherein the first inductor and the second inductor are magnetically coupled.

Example 11 includes the circuit of example 9, wherein the second transistor is a p-channel metal-oxide semiconductor (PMOS) transistor.

Example 12 includes a system comprising input stage circuitry including a first output, equalizer circuitry including a first transistor including a gate terminal coupled to the first output, a first inductor including a first inductor terminal coupled to a first source terminal of the first transistor, a second transistor including a second drain terminal coupled to a second inductor terminal of the first inductor, a capacitor coupled to the first inductor terminal and to the first source terminal of the first transistor, and gain stage circuitry including a first input coupled to a first drain terminal of the first transistor.

Example 13 includes the system of example 12, wherein the equalizer circuitry includes a third transistor, a second inductor including a third inductor terminal coupled to a third drain terminal of the third transistor and a fourth inductor terminal coupled to a third source terminal of the third transistor, a fourth transistor, and a third inductor including a fifth inductor terminal coupled to a fourth drain terminal of the fourth transistor and a sixth inductor terminal coupled to a fourth source terminal of the fourth transistor.

Example 14 includes the system of example 13, wherein the second inductor and the third inductor are magnetically coupled to the first inductor.

Example 15 includes the system of example 13, wherein the third transistor includes a third gate terminal configured to receive a first control signal and the fourth transistor includes a fourth gate terminal configured to receive a second control signal.

Example 16 includes the system of example 12, wherein the second transistor is a variable resistor.

Example 17 includes the system of example 12, wherein the equalizer circuitry further includes a third transistor including a third gate terminal coupled to the first drain terminal of the first transistor and a third drain terminal coupled to the first drain terminal of the first transistor, and a second inductor including a third inductor terminal coupled to the first drain terminal and to the third drain terminal and a fourth inductor terminal coupled to the first input.

Example 18 includes the system of example 17, wherein the second inductor is a series peaking inductor.

Example 19 includes the system of example 17, wherein the third transistor is a diode connected p-channel metal-oxide semiconductor (PMOS) transistor.

Example 20 includes the system of example 12, wherein the capacitor is a digitally controlled capacitor.

Example 21 includes the system of example 12, further including output stage circuitry including a second input coupled to a second output of the gain stage circuitry, and a third output configured to be coupled to a vertical-cavity surface emitting laser.

Example 22 includes a method comprising obtaining a modulated input signal at a first frequency, causing a complex-zero in a first frequency response at the first frequency of the modulated input signal, and cancelling an effect of a complex pole in a second frequency response at the first frequency of the modulated input signal based on the first frequency response.

Example 23 includes the method of example 22, further comprising extending a bandwidth of the second frequency response based on the complex-zero in the first frequency response.

Example 24 includes the method of example 22, wherein the effect of the complex pole includes gain peaking and group delay distortion.

Example 25 includes an apparatus comprising means for performing a method as described in any one or more of examples 22-24.

Example 26 includes a machine-readable storage including machine-readable instructions which, when executed, cause a computer to implement a method as described in any one or more of examples 22-24.

Example 27 includes a computer program comprising instructions which, when the program is executed by a computer, cause the computer to carry out the method as described in any one or more of examples 22-24.

The following claims are hereby incorporated into this Detailed Description by this reference. Although certain example systems, apparatus, articles of manufacture, and methods have been disclosed herein, the scope of coverage of this patent is not limited thereto. On the contrary, this patent covers all systems, apparatus, articles of manufacture, and methods fairly falling within the scope of the claims of this patent.

1. A circuit comprising:
driver circuitry including a first input; and
equalizer circuitry including:
a second input;
a first output coupled to the first input;
a transistor including a gate terminal, a drain terminal, and a source terminal, the gate terminal coupled to the second input and the drain terminal coupled to the first output;
an inductor including a first inductor terminal and a second inductor terminal, the first inductor terminal coupled to the source terminal of the transistor;
a resistor coupled to the second inductor terminal; and
a capacitor including a first terminal and a second terminal coupled to the source terminal and to the first inductor terminal and the second terminal coupled to ground.

2. The circuit of claim 1, wherein the equalizer circuitry further includes a load coupled to the drain terminal of the transistor and coupled to the first output, the load including a series peaking inductor.

3. The circuit of claim 1, wherein the equalizer circuitry further includes a load coupled to the drain terminal of the transistor and coupled to the first output, the load including a shunt peaking inductor.

4. The circuit of claim 1, wherein the equalizer circuitry is a continuous time linear equalizer circuit.

5. The circuit of claim 1, wherein the transistor is an n-channel metal-oxide semiconductor (NMOS) transistor.

6. The circuit of claim 1, wherein the driver circuitry includes a second output configured to be coupled to a wideband system.

7. The circuit of claim 6, wherein the wideband system is a vertical cavity surface emitting laser.

8. The circuit of claim 1, wherein the driver circuitry includes a second output configured to be coupled to a bandwidth extension system.

9. The circuit of claim 1, wherein the transistor is a first transistor, the inductor is a first inductor, the resistor is a first resistor, and the capacitor is a first capacitor, the gate terminal is a first gate terminal, the drain terminal is a first drain terminal, and the source terminal is a first source terminal, the equalizer circuitry further including:
a second transistor including a second gate terminal, a second drain terminal, and a second source terminal, the second gate terminal coupled to the second input and the second drain terminal coupled to the first drain terminal of the first transistor and to the first output;
a second inductor including a third inductor terminal and a fourth inductor terminal, the third inductor terminal coupled to the second source terminal;
a second resistor coupled to the fourth inductor terminal; and
a second capacitor coupled to the second source terminal and the third inductor terminal.

10. The circuit of claim 9, wherein the first inductor and the second inductor are magnetically coupled.

11. The circuit of claim 9, wherein the second transistor is a p-channel metal-oxide semiconductor (PMOS) transistor.

12. A system comprising:
input stage circuitry including a first output;
equalizer circuitry including:
a first transistor including a gate terminal coupled to the first output;
a first inductor including a first inductor terminal coupled to a first source terminal of the first transistor;
a second transistor including a second drain terminal coupled to a second inductor terminal of the first inductor;
a capacitor coupled to the first inductor terminal and to the first source terminal of the first transistor; and
gain stage circuitry including a first input coupled to a first drain terminal of the first transistor.

13. The system of claim 12, wherein the equalizer circuitry includes:
a third transistor;
a second inductor including a third inductor terminal coupled to a third drain terminal of the third transistor and a fourth inductor terminal coupled to a third source terminal of the third transistor;
a fourth transistor; and
a third inductor including a fifth inductor terminal coupled to a fourth drain terminal of the fourth transistor and a sixth inductor terminal coupled to a fourth source terminal of the fourth transistor.

14. The system of claim 13, wherein the second inductor and the third inductor are magnetically coupled to the first inductor.

15. The system of claim 13, wherein the third transistor includes a third gate terminal configured to receive a first control signal and the fourth transistor includes a fourth gate terminal configured to receive a second control signal.

16. The system of claim 12, wherein the second transistor is a variable resistor.

17. The system of claim 12, wherein the equalizer circuitry further includes:
a third transistor including a third gate terminal coupled to the first drain terminal of the first transistor and a third drain terminal coupled to the first drain terminal of the first transistor; and
a second inductor including a third inductor terminal coupled to the first drain terminal and to the third drain terminal and a fourth inductor terminal coupled to the first input.

18. The system of claim 17, wherein the second inductor is a series peaking inductor.

19. The system of claim 17, wherein the third transistor is a diode connected p-channel metal-oxide semiconductor (PMOS) transistor.

20. The system of claim 12, wherein the capacitor is a digitally controlled capacitor.

21-27. (canceled)
